(19) United States
(12) Patent Application Publication
(10) Pub. No.: US 2026/0006766 A1
(43) Pub. Date: Jan. 1, 2026

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Ching-Wang YAO, New Taipei City (TW); Hsin-Cheng LIN, Taipei City (TW); Tsai-Yu CHUNG, Hsinchu City (TW); Tao CHOU, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/754,622

(22) Filed: Jun. 26, 2024

(51) Int. Cl. H10B 10/00

(52) U.S. Cl. CPC H10B 10/125

(57) ABSTRACT

A method includes forming a first bottom-tier pull-up transistor and a second bottom-tier pull-up transistor over a substrate, wherein the first and second bottom-tier pull-up transistors are comprised in a static random access memory (SRAM) cell; forming a first middle-tier pull-down transistor and a second middle-tier pull-down transistor over the first and second bottom-tier pull-up transistors, wherein the first and second middle-tier pull-down transistors are comprised in the SRAM cell; forming a first top-tier pass-gate transistor, a second top-tier pass-gate transistor, a third top-tier pass-gate transistor, and a fourth top-tier pass-gate transistor over the first and second middle-tier pull-down transistors, wherein the first, second, third, and fourth top-tier pass-gate transistors are comprised in the SRAM cell.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a layout of a static random access memory (SRAM) array with a sensing amplifier and a word line driver in accordance with some embodiments of the present disclosure.

FIGS. 2A and 2B illustrate circuit diagrams in accordance with some embodiments of the present disclosure.

FIGS. 3A and 3B illustrate perspective views of semiconductor structures in accordance with some embodiments of the present disclosure.

FIG. 3C illustrates an enlarge view of a region C1 in FIG. 3B in accordance with some embodiments of the present disclosure.

FIGS. 4A and 4B illustrate layouts of semiconductor structures in top tier in accordance with some embodiments of the present disclosure.

FIGS. 5-10B illustrate cross-sectional views obtained from reference cross-sections A1-A1′, B1-B1′, A2-A2′, B2-B2′, A3-A3′, B3-B3′, A4-A4′, B4-B4′, A5-A5′, B5-B5′, A6-A6′, B6-B6′, in FIGS. 3A and 3B.

FIGS. 11A and 11B show a comparative analysis of read times between two types of SRAM bit-cells across different positions within an SRAM array in accordance with some embodiments of the present disclosure.

FIGS. 11C and 11D show a comparative analysis of energy delay products between two types of SRAM bit-cells across different positions within an SRAM array in accordance with some embodiments of the present disclosure.

FIGS. 12-55B illustrate schematic views of intermediate stages in the formation of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

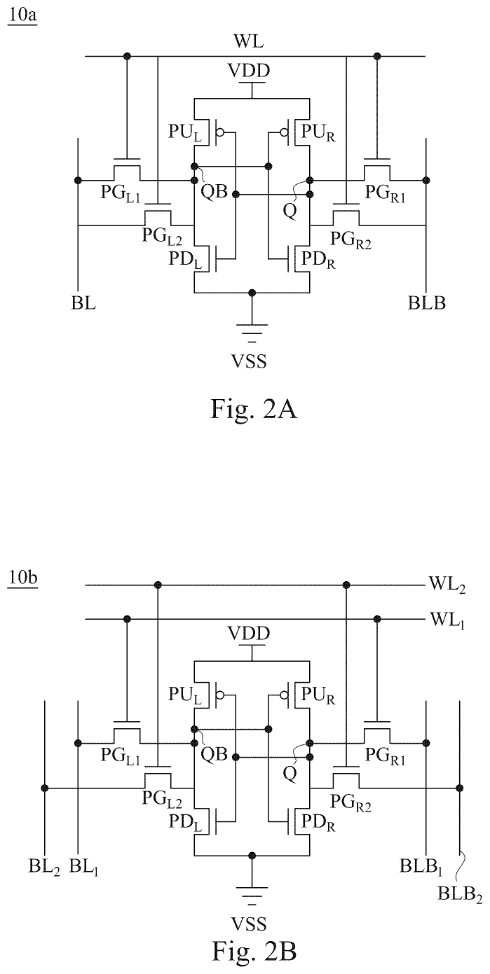

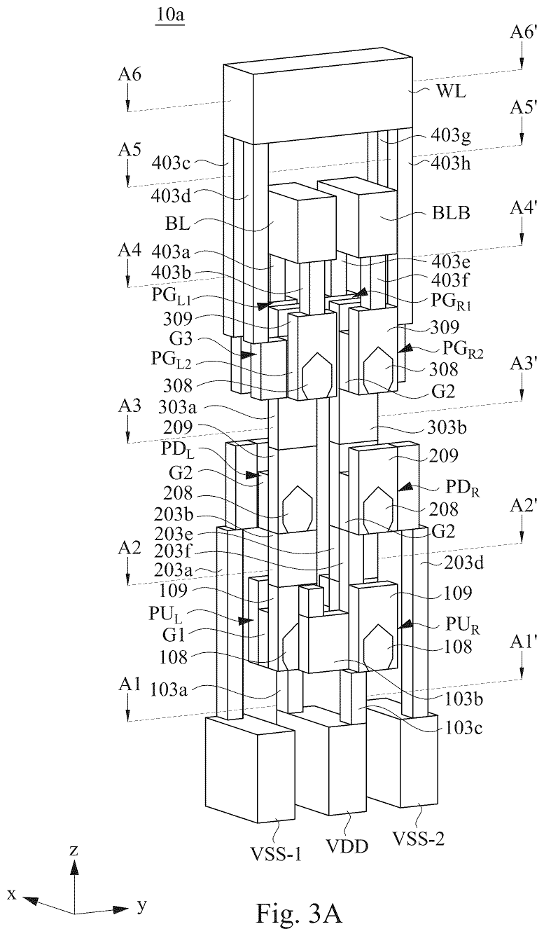

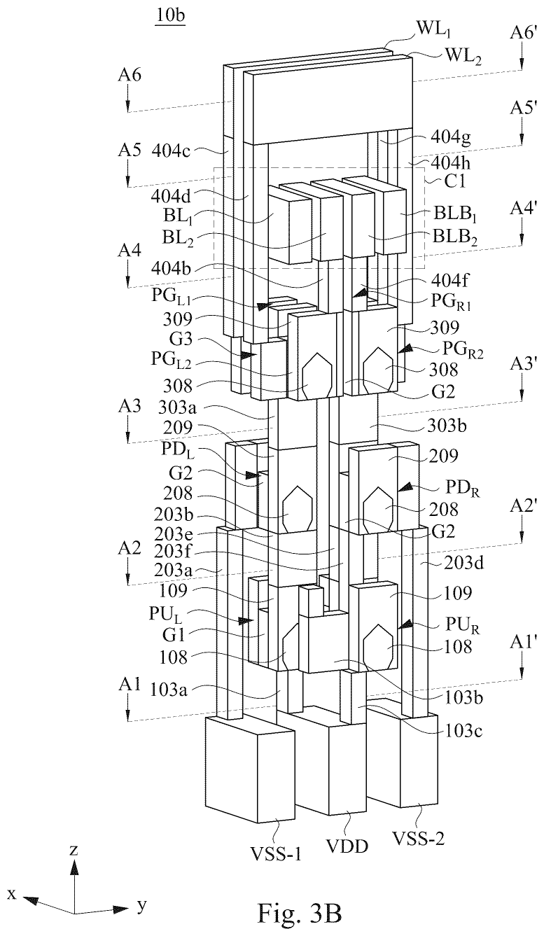

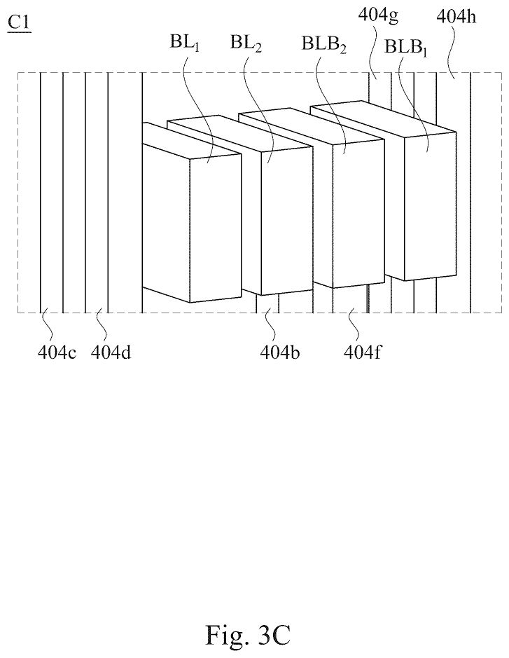

Throughout the evolution of integrated circuits (ICs), there has been a general trend of increasing functional density, which refers to the number of interconnected devices per chip area, while reducing the geometry size, representing the smallest component or line that can be created using the fabrication process. In order to enhance the functional density of IC structures, a proposed approach involves the use of complementary field-effect transistors (CFETs), where a p-type FET and an n-type FET are vertically stacked. The present disclosure in various embodiments provides an improved static random access memory (SRAM) bit-cell configurations, focusing on read-enhanced and dual-port versions, both utilizing a three-tier architecture with 8 transistors (8T), maintaining the same physical footprint (e.g., 4 transistors footprint) as a standard 6T high-density SRAM bit-cell. The read-enhanced SRAM Bit-cell (see FIGS. 2A and 3A) can incorporate two pairs of pass-gate transistors on the top-tier, doubling the transistor strength for improved read operations without increasing the bit-cell area. The dual-port SRAM bit-cell (see FIGS. 2B and 3B) can incorporates two pairs of pass-gate transistors, each controlled by separate word lines, allowing independent accesses to the memory cell, which supports operations like simultaneous reads/writes. Additionally, the read-enhanced/dual-port SRAM Bit-cell can have the same transistor configuration as the 6T SRAM bit-cell for the pull-down and pull-up transistors.

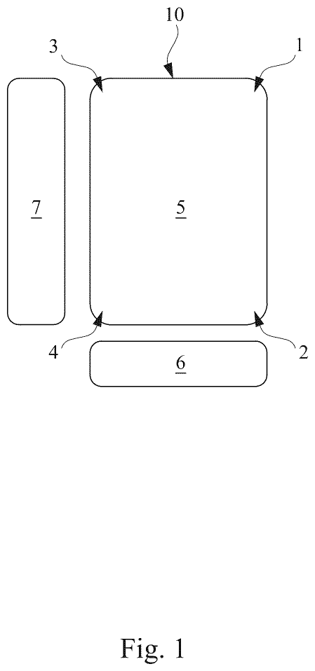

Reference is made to FIG. 1. FIG. 1 illustrates a layout of a static random access memory (SRAM) array 5 with a sensing amplifier 6 and a word line driver 7 in accordance with some embodiments of the present disclosure. The SRAM array 5 illustrates in FIG. 1 includes of multiple SRAM bit-cells. The sensing amplifier 6 is strategically positioned on one side of the SRAM array 5, facilitating rapid and sensitive detection of the stored data's state by amplifying the signal difference between the bit lines. The word line driver 7 can be positioned on the opposite side of the SRAM array 5, activating the word lines that enable access to the stored data in the respective bit-cells. The SRAM bit-cells can be at least placed at four corner positions 1, 2, 3, and 4 within the SRAM array 5. Each position offers a unique proximity to the sensing amplifier 6 and the word line driver 7, influencing the performance of the bit-cells. In some embodiments, the SRAM bit-cell on the position 1 can be close to both the sensing amplifier 6 and the word line driver 7, potentially offering the quickest access and response times. The SRAM bit-cell on the position 2 can be near the sensing amplifier 6 but distant from the word line driver 7, possibly experiencing slower access due to the longer word line drive times. The SRAM bit-cell on the position 3 can be near the word line driver 7 but distant from the sensing amplifier 6, which might affect the speed and accuracy of data sensing. The SRAM bit-cell on the position 4 can be distant from both the sensing amplifier 6 and the word line driver 7, likely resulting in the slowest performance in terms of both access and sensing. Due to the varying distances of the bit-cells from the sensing amplifier 6 and word line driver 7, the performance across the SRAM array 5 can be inconsistent. The bit-cells closer to these components might perform better than those positioned farther away.

Therefore, to address the performance discrepancies and enhance the overall functionality of the SRAM array 5, the disclosure in various embodiments provides circuit diagrams and structures as shown in subsequent figures (i.e., FIGS. 2A and 2B). These enhancements can be aimed at normalizing the performance across different bit-cell locations within the SRAM array 5 by adjusting the circuit layouts, enhancing connectivity, and/or integrating additional components to stabilize and speed up the operation regardless of a bit-cell's specific location in the SRAM array 5.

Reference is made to FIGS. 2A and 2B. FIGS. 2A and 2B illustrate circuit diagrams in accordance with some embodiments of the present disclosure. Specifically, the circuit diagrams illustrated in FIGS. 2A and 2B are two configurations of SRAM bit-cells, such as a read-enhanced SRAM bit-cell 10a and a dual-port SRAM bit-cell 10b. While FIG. 2B illustrates embodiments of the SRAM bit-cell 10b with a configuration than the SRAM bit-cell 10a in FIG. 2A, the present disclosure may repeat reference numerals and/or letters in the various examples. This repetition is for the purpose of simplicity and clarity and does not in itself dictate a relationship between the various embodiments and/or configurations discussed.

As shown in FIG. 2A, the read-enhanced SRAM bit-cell 10a can include two pairs of pass-gate transistors PG_{L1}, PG_{L2}, PG_{R1}, and PG_{R2}, enabling and disabling access to the storage elements. Additionally, the read-enhanced SRAM bit-cell can include a pair of pull-down transistors PD_{L} and PD_{R} to drive the bit-cell to a logical low state during write operations. Furthermore, the read-enhanced SRAM bit-cell can include a pair of pull-up transistors PU_{L} and PU_{R} to drive the cell to a logical high state, ensuring the stability of the stored data. Therefore, the transistor ratio (e.g., pull-down: pull-up: pass-gate) can be 1:1:2. All pass-gate transistors PG_{L1}, PG_{L2}, PG_{R1}, and PG_{R2} can be connected to a common word line WL, simplifying the control but enhancing the read operation by providing stronger or faster access to the storage nodes. The source/drain nodes of the pass-gate transistors PG_{L1} and PG_{L2} can be connected to a common data line (i.e., bit line BL), and the source/drain nodes of the pass-gate transistors PG_{R1} and PG_{R2} can be connected to a common complementary bit line BLB. In some embodiment, the complementary bit line BLB can interchangeable referred to as a bit line bar.

The term “read-enhanced” can refer to modifications made to improve the read functionality of the SRAM bit-cell 10a, increasing the speed and reliability of read operations, which are for high-performance applications that require quick data access. The additional pass-gate transistors PG_{L2} and PG_{R2} can provide a stronger and quicker path for reading data from the storage nodes, resulting in reduced access time, as the bit lines can be charged or discharged more rapidly. Additionally, by doubling the number of pass-gate transistors PG_{L2} and PG_{R2}, the SRAM bit-cell 10a can drive the bit lines BL and/or bit line BLB with greater strength, thus improving the signal integrity and reducing the likelihood of errors caused by voltage fluctuations or noise.

As shown in FIG. 2B, similar to the read-enhanced SRAM bit-cell 10a, the dual-port SRAM bit-cell 10b can includes two pairs of pass-gate transistors PG_{L1}, PG_{L2}, PG_{R1}, and PG_{R2}. Each read-enhanced SRAM bit-cell 10a also can include a pair of pull-down transistors PD_{L} and PD_{R} and a pair of pull-up transistors PU_{L} and PU_{R}, mirroring the setup of the read-enhanced bit-cell 10a. The difference between the read-enhanced SRAM bit-cell 10a and the dual-port SRAM bit-cell 10b is that each pair of pass-gate transistors PG_{L1}, PG_{L2}, PG_{R1}, and PG_{R2} of the dual-port SRAM bit-cell 10b is connected to different word lines WL₁ and WL₂, allowing for independent access to different parts of the SRAM bit-cell 10b. The transistor ratio (e.g., pull-down: pull-up: pass-gate for first port: pass-gate for second port) can be 1:1:1:1. The source/drain nodes of the pass-gate transistors PG_{L1} and PG_{L2} can be connected to separate data lines (i.e., bit line BL₁ for the pass-gate transistors PG_{L1} and bit line BL₂ for the pass-gate transistor PG_{L2}) and similarly for the pass-gate transistor PG_{R1} and PG_{R2} (i.e., bit line BLB₁ for the pass-gate transistors PG_{R1} and bit line BLB₂ for the pass-gate transistor PG_{R2}). In some embodiment, the complementary bit line BLB₁/BLB₂ can interchangeable referred to as a bit line bar.

The term “dual-port” can indicate that the SRAM bit-cell 10b can support two independent access ports, allowing the SRAM bit-cell 10b to handle two separate access (e.g., read/write) operations simultaneously, which are for the systems that require high throughput and flexibility in memory management. In the SRAM bit-cell 10b, each pair of pass-gate transistors can be controlled by separate word lines WL₁ and WL₂, allowing independent operations on each port without interfering with each other, which is for applications requiring high data bandwidth and parallel processing. Additionally, the ability to perform two operations concurrently (e.g., reading from one port while writing to another) can increase the throughput of the memory system. Therefore, the additional pass-gate transistors (e.g., pass-gate transistor PG_{L2} and PG_{R2}) in both the read-enhanced and dual-port SRAM bit-cells 10a and 10b can enhance their respective functionalities (e.g., speed and stability in the read-enhanced SRAM bit-cell 10a, and concurrency and throughput in the dual-port SRAM bit-cell 10b). These enhancements can address performance challenges in computing environments, making them invaluable for applications requiring robust, high-speed memory solutions.

Referring back to FIGS. 2A and 2B, the read-enhanced and dual-port SRAM bit-cells 10a and 10b illustrate each can use eight transistors (8T). The SRAM bit-cell 10b can have an additional functionality in the form of write port, and thus the SRAM bit-cell 10b can be referred to as a dual port 8T SRAM bit-cell. In FIG. 2A, a pair of pass-gates PG_{L1}, PG_{L2}, PG_{R1}, and PG_{R2} can couple a pair of data lines referred to as bit lines BL and BLB to inversely related storage nodes QB and Q, respectively. The bit lines BL and BLB can form a complementary pair of data lines. In some embodiments, these paired data lines shown in FIG. 2A may be coupled to a differential sense amplifier (see FIG. 1); the differential voltage can be sensed and amplified. This amplified sensed output signal may then be output as data to other logic circuitry in the device.

In FIG. 2B, a pair of pass-gates PG_{L1} and PG_{R1} can couple a pair of data lines referred to as bit lines BL₁ and BLB₁ to inversely related storage nodes QB and Q, respectively, and a pair of pass-gates PG_{L2} and PG_{R2} can couple a pair of data lines referred to as bit lines BL₂ and BLB₂ to inversely related storage nodes QB and Q, respectively. The bit lines BL₁ and BLB₁ can form a complementary pair of data lines, and the bit lines BL₂ and BLB₂ can form a complementary pair of data lines. In some embodiments, these paired data lines shown in FIG. 2B may be coupled to a differential sensing amplifier 6 (see FIG. 1); the differential voltage can be sensed and amplified. This amplified sensed output signal may then be output as data to other logic circuitry in the device.

A supply voltage VDD, which may be from 0.6 Volts to 3.0 or more volts, depending on the technology node, is shown. The pull up transistors PU_{L} and PU_{R} of the read-enhanced/dual-port SRAM bit-cell 10a/10b can couple the positive supply to one or the other storage nodes, depending on the state of the SRAM bit-cell 10a/10b. A second supply voltage VSS, usually placed at ground, is shown. Two pull down transistors PD_{L} and PD_{R} can couple negative or ground voltage VSS to one or the other storage nodes labeled QB and Q, depending on the state of the SRAM bit-cell 10a/10b. The SRAM bit-cell 10a/10b can be a latch that will retain its data state indefinitely so long as the supplied power is sufficient to operate the circuit correctly.

Two invertors formed of transistors PU_{R}, PU_{L}, PD_{R}, PD_{L}, PG_{R1}, PG_{R2}, PG_{L1}, and PG_{L2} can be “cross coupled” and they can operate to reinforce the stored charge on the storage nodes QB and Q continuously. The two storage nodes QB and Q can be inverted one from the other, as shown in the figure. When the SRAM bit-cell 10a as shown in FIG. 2A is written to, complementary write data signals can placed on the bit line pair (i.e., bit lines BL and BLB). A positive control signal on the word line WL can be coupled to the gates of the pass-gate transistors PG_{R1}, PG_{R2}, PG_{L1}, and PG_{L2}. In some embodiments, the word line WL can be a write only word line in the SRAM bit-cell 10a. The transistors PU_{L}, PD_{R} PU_{L}, PD_{R} can be sized such that the data on the bit lines BL and BLB may overwrite the stored data and thus write, or program, the SRAM bit-cell 10a. When the SRAM bit-cell 10a is in read from, a positive voltage is placed on the word line WL, and the pass-gate transistors PG_{R1}, PG_{R2}, PG_{L1}, and PG_{L2} allow the bit lines BL and BLB to be coupled to, and receive the data from, the storage nodes QB and Q.

When the SRAM bit-cell 10b as shown in FIG. 2B is written to, complementary write data signals can placed on the first bit line pair (i.e., bit lines BL₁ and BLB₁) and/or the second bit line pair (i.e., bit lines BL₂ and BLB₂). A first positive control signal on the word line WL₁ can be coupled to the gates of the pass-gate transistors PG_{R1} and PG_{L1} and/or a second positive control signal on the word line WL₂ can be coupled to the gates of the pass-gate transistors PG_{R2} and PG_{L2}. In some embodiments, the word lines WL₁ and WL₂ can be write only word lines in the SRAM bit-cell 10b. The transistors PU_{L}, PD_{R} PU_{L}, PD_{R} can be sized such that the data on the bit lines BL₁, BL₂, BLB₁, and BLB₂ may overwrite the stored data and thus write, or program, the SRAM bit-cell 10b. When the SRAM bit-cell 10b is in read from, a positive voltage is placed on the word line WL₁ and/or the word line WL₂, and the pass-gate transistors PG_{R1}, PG_{R2}, PG_{L1}, and PG_{L2} allow the bit lines BL₁, BL₂, BLB₁, BLB₂ to be coupled to, and receive the data from, the storage nodes QB and Q. Unlike a dynamic memory cell, the SRAM bit-cell 10a/10b does not lose its stored state during a read if the supply voltage VDD is maintained at a sufficiently high level, so no “write back” operation is required after a cell read.

In some embodiments, the transistors PD_{R}, PD_{L}, PG_{R1}, PG_{R2}, PG_{L1}, and PG_{L2} can be of a first conductivity type, and the transistors PU_{R} and PU_{L} be of a second conductivity type opposite to the first conductivity type. By way of example and not limitation, the transistors PD_{R}, PD_{L}, PG_{R1}, PG_{R2}, PG_{L1}, and PG_{L} may be n-type transistors (e.g., N-type Metal-Oxide-Semiconductor (NMOS) transistors), and the PU_{R} and PU_{L} may be p-type transistors (e.g., P-type Metal-Oxide-Semiconductor (PMOS) transistors). In some embodiments, the transistors pRP₁, pRP₂, may be p-type transistors (e.g., PMOS transistors), and the transistors PU_{R} and PU_{L} may be n-type transistors (e.g., NMOS transistors).

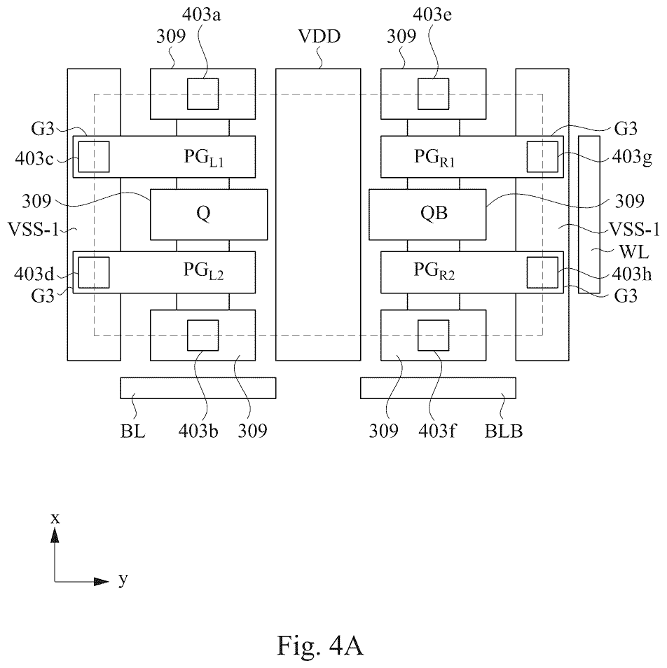

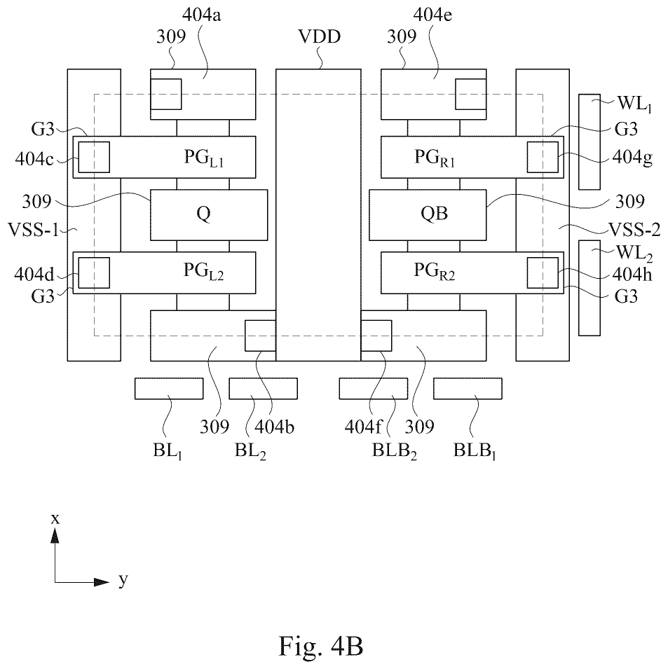

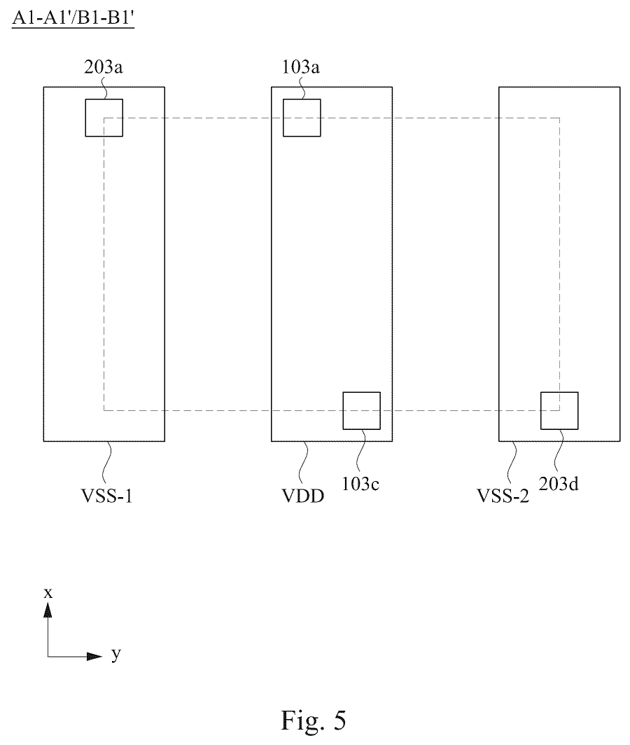

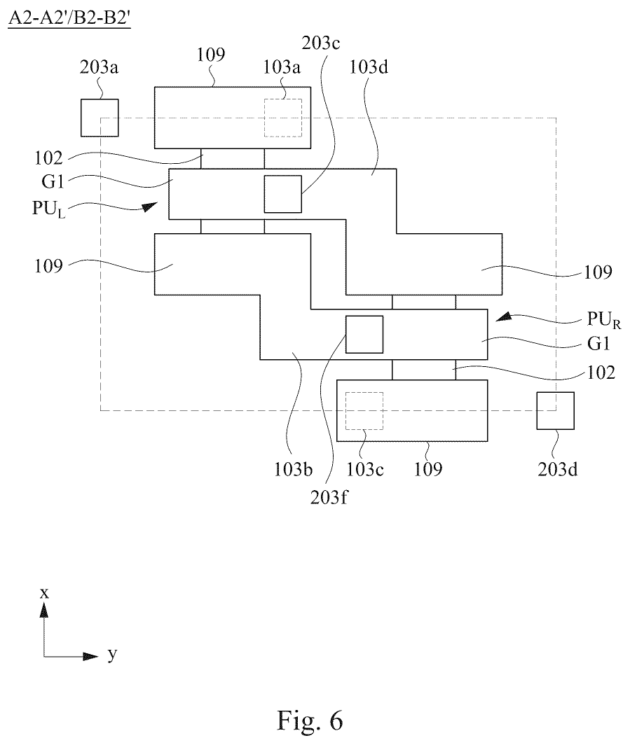

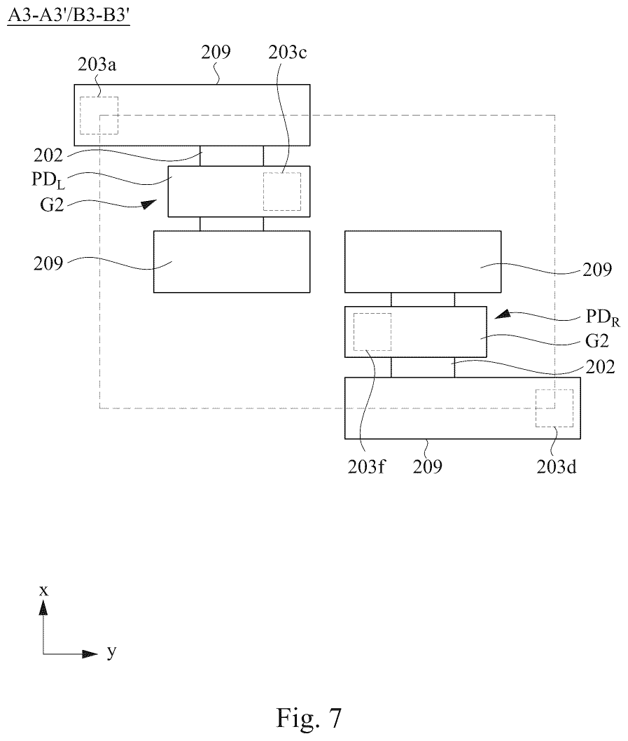

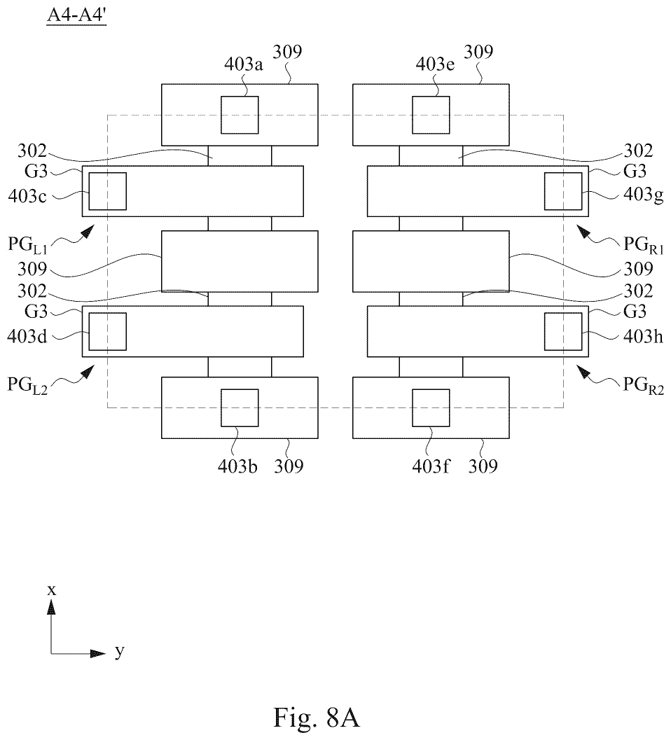

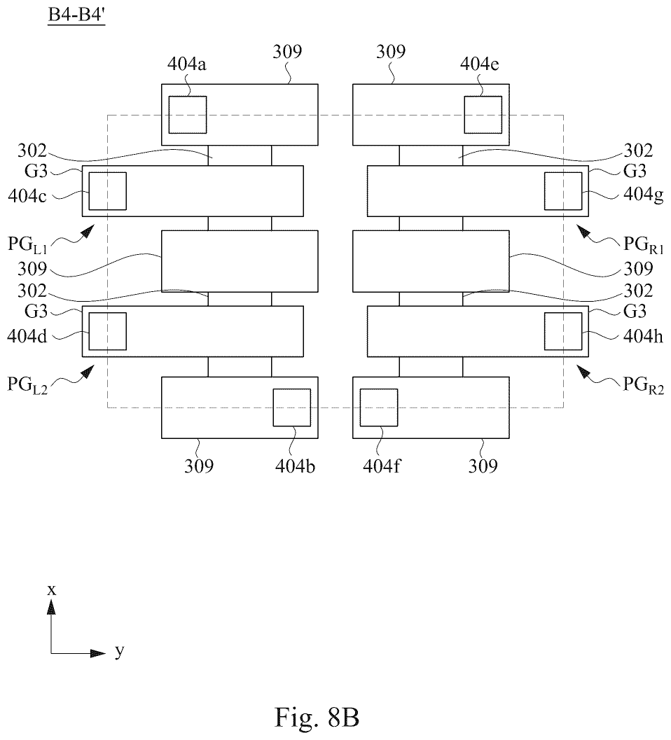

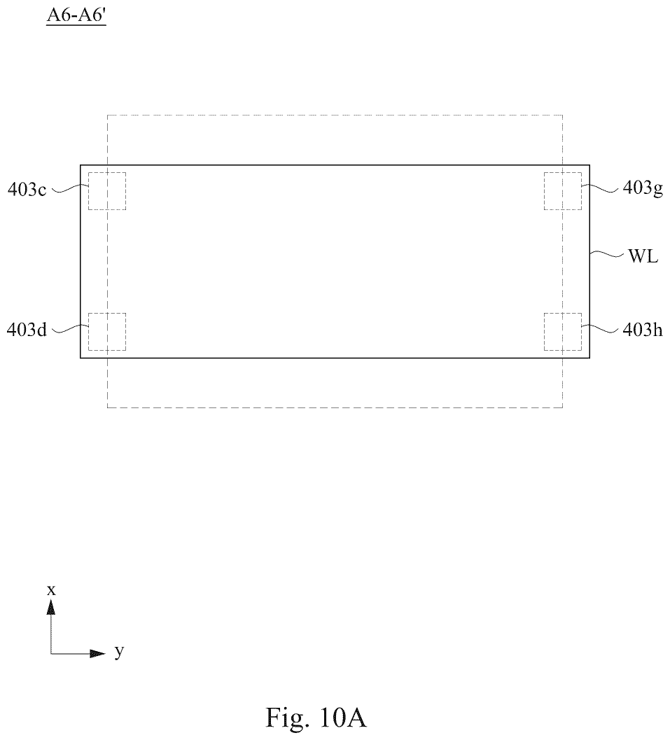

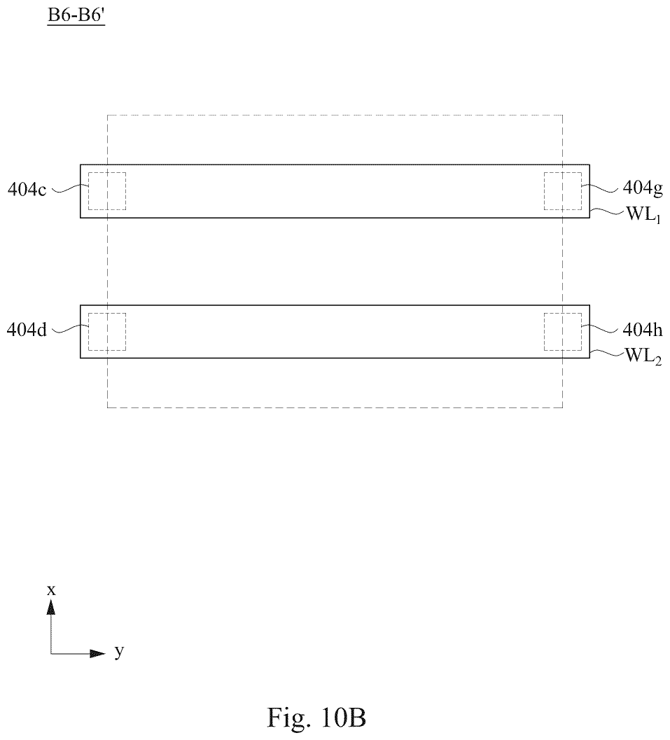

Reference is made to FIGS. 3A, 4A, 5-7, 8A, 9A, and 10A. FIG. 3A illustrates a perspective view of a semiconductor structure of the SRAM bit-cell 10a shown in FIG. 2A in accordance with some embodiments of the present disclosure. FIG. 4A illustrates a layout of a semiconductor structure in top tier in accordance with some embodiments of the present disclosure. FIGS. 5-7, 8A, 9A, and 10A illustrate cross-sectional views obtained from reference cross-sections A1-A1′, A2-A2′, A3-A3′, A4-A4′, A5-A5′, and A6-A6′ in FIG. 3A. In some embodiments, the semiconductor structure can include transistors PU_{R} and PU_{L} (see FIGS. 3A and 6) as bottom-tier transistors, the transistors PD_{R} and PD_{L} (see FIGS. 3A and 7) as middle-tier transistors, and the transistors PG_{R1}, PG_{R2}, PG_{L.}, and PG_{L2} (see FIGS. 3A and 8A) as top-tier transistors. In other words, the transistors PU_{R} and PU_{L} can be at a first level height, and the transistors PD_{R} and PD_{L} can be at a second level height higher than the first level height, and the transistors PG_{R1}, PG_{R2}, PG_{L1}, and PG_{L2} can be at a third level height higher than the second level height.

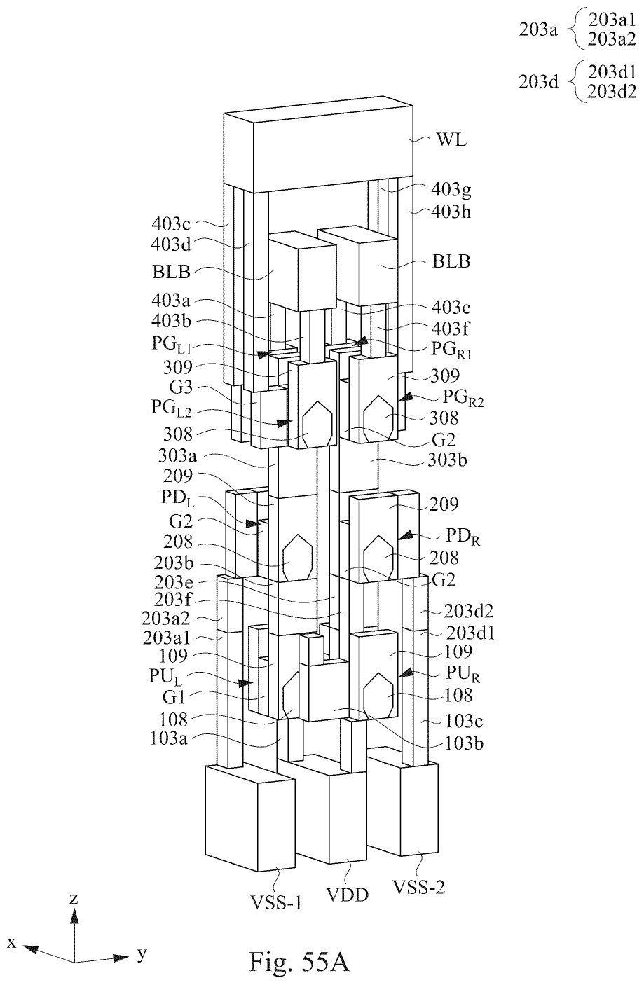

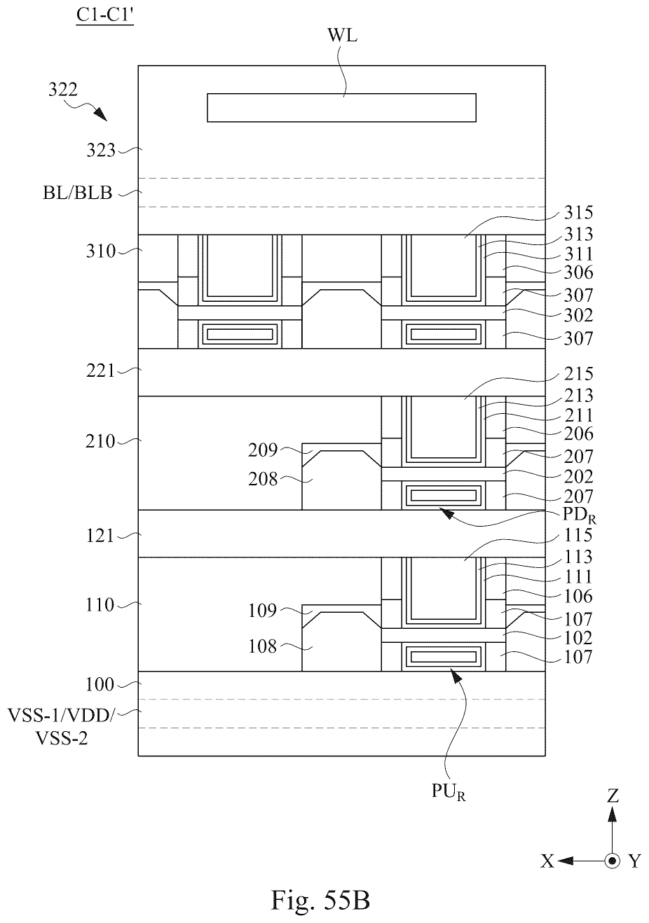

In some embodiments, a footprint of the transistor PD_{L} on a substrate 100 (see FIGS. 55A and 55B) can vertically overlap with a footprint of the transistor PU_{L} on the substrate 100, and a footprint of the transistor PD_{R} can vertically overlap with a footprint of the transistor PU_{R} on the substrate 100. A footprint of the transistor PG_{L1} on the substrate 100 can vertically overlap with a footprint of the transistor PD_{L} on the substrate 100, and a footprint of the transistor PG_{R2} on the substrate 100 can vertically overlap with a footprint of the transistor PD_{R} on the substrate 100. On the other hand, the channel layer 202 (see FIG. 7) of the transistor PD_{L} can vertically overlap with the channel layer 102 (see FIG. 6) of the transistor PU_{L} on the substrate 100, and the channel layer 202 of the transistor PD_{R} can vertically overlap with the channel layer 102 of the transistor PU_{R}. The channel layer 302 (see FIG. 8A) of the transistor PG_{L1} can vertically overlap with the channel layer 202 of the transistor PD_{L}, and the channel layer 302 of the transistor PG_{R2} can vertically overlap with the channel layer 202 of the transistor PD_{R}. In some embodiments, the transistors PU_{R} and PU_{L}, PD_{R}, PD_{L}, PG_{R1}, PG_{R2}, PG_{L1}, and PG_{L2} can be positioned at more/less than 3-tiers.

As shown in FIGS. 3A and 6, the transistors PU_{R} and PU_{L} each can include a channel layer 102, a gate structure G1 wrapping around the channel layer 102, and source/drain regions 108 (see FIG. 3A) on opposite sides of the gate structure G1 and connected to the channel layer 102. The transistors PD_{R} and PD_{L} each can include the channel layer 202, a gate structure G2 (see FIG. 3A) wrapping around the channel layer 202, and source/drain regions 208 on opposite sides of the gate structure G2 and connected to the channel layer 202. The transistors PG_{R1}, PG_{R2}, PG_{L1}, and PG_{L2} each can include a channel layer 302, a gate structure G3 (see FIG. 3A) wrapping around the channel layer 302, and source/drain regions 308 on opposite sides of the gate structure G3 and connected to the channel layer 302. In some embodiments, the transistors in the SRAM bit cell 10a can include various channel geometries such as nanosheets, FinFETs, nanowires, and TreeFETs, etc. In some embodiments, the channel layer 102, 202, and/or 302 can be interchangeable referred to as a channel pattern, a channel region, a channel line, a semiconductive layer, or a semiconductive nanostructure. In some embodiments, the source/drain region 108, 208 and/or 308 can be interchangeably referred to as a source/drain pattern, an epitaxial pattern, a source/drain structure, or an epitaxial structure. In some embodiments, the gate structure G1, G2, and/or G3 can be interchangeable referred to as a gate, a gate pattern, a gate strip, a gate layer, a gate layer, a functional gate, a metal layer, or a metal strip.

With regard to the transistors PU_{R} and PU_{L} in the bottom-tire as shown in FIGS. 3A, 5, and 6, a first one of the source/drain regions 108 of the transistor PU_{L} can be electrically connected to the underlying voltage source line VDD through a contact 103a. A second one of the source/drain regions 108 of the transistor PU_{L} can be electrically connected to the gate structure G1 of the transistor PU_{R} through a contact 103b. Similarly, a first one of the source/drain regions 108 of the transistor PU_{R} is electrically connected to the underlying voltage source line VDD through a contact 103c. A second one of the source/drain regions 108 of the transistor PU_{R} can be electrically connected to the gate structure G1 of the transistor PU_{L} through a contact 103d.

With regard to the transistors PD_{R} and PD_{L} in the middle-tire as shown in FIGS. 3A and 7, a first one of the source/drain regions 208 of the transistor PD_{L} is electrically connected to the underlying ground line VSS-1 through the contact 203a. A second one of the source/drain regions 208 of the transistor PD_{L} is electrically connected to the underlying source/drain region 208 of the transistor PU_{L} through the contact 203b (see FIG. 3A) and the underlying source/drain contact 109 and electrically connected a sharing overlying source/drain region 308 of the transistors PG L. 2 and PG_{L2} through the contact 303a (see FIG. 3A). Furthermore, the gate structure G2 of the transistor PD_{L} is electrically connected to the gate structure G1 of the underlying transistor PU_{L} through a contact 203c (see FIGS. 6 and 7). Similarly, a first one of the source/drain regions 208 of the transistor PD_{R} is electrically connected to the underlying ground line VSS-2 through the contact 203d. A second one of the source/drain regions 208 of the transistor PD_{R} is electrically connected to the underlying source/drain region 208 of the transistor PU_{R} through the contact 203e (see FIG. 3A) and the underlying source/drain contact 109 and electrically connected a sharing overlying source/drain region 308 of the transistors PG_{L2} and PG_{L2} through the contact 303b. Furthermore, the gate structure G2 of the transistor PD_{L} is electrically connected to the gate structure G1 of the underlying transistor PU_{L} through a contact 203f.

In some embodiments, the voltage source line VDD and/or the ground line VSS-1/VSS-2 can be interchangeable referred to as a backside power line or a buried metal supplying power line. In some embodiments, the voltage source line VDD and ground lines VSS-1 and VSS-2 can be collectively referred to a backside power delivery network (BSPDN). In some embodiments, by integrating backside power delivery network and complementary FET technologies, the implementation of the multi-port CFET SRAM can have a reduction in routing complexity. This approach not only streamlines the internal architecture of the SRAM cell 10a but also enhances overall circuit efficiency and reliability. In some embodiments, the voltage source line VDD and the ground lines VSS-1 and VSS-2 can be manufactured to position at back end of line (BEOL) over a front-side of the SRAM cell 10a.

With regard to the transistors PG_{L1}, PG_{L2}, PG_{R1}, and PG_{R2} in the top-tier as shown in FIGS. 3A, 4A, 8A, 9A, and 10A, non-sharing source/drain regions 308 of the transistors PG_{L1} and PG_{L2} are electrically connected to the overlying bit line BL through contacts 403a and 403b, respectively. The gate structures G3 of the transistors PG_{L1} and PG_{L2} are electrically connected to the overlying word line WL through the contacts 403c and 403d. Similarly, non-sharing source/drain regions 308 of the transistor PG_{R1} and PG_{R2} are electrically connected to the overlying bit line BLB through contacts 403e and 403f, respectively. The gate structure G3 of the transistor PG_{R1} and PG_{R2} are electrically connected to the overlying word line WL through the contacts 403g and 403h.

Reference is made to FIGS. 3B, 3C, 4B, 5-7, 8B, 9B, and 10B. FIG. 3B illustrates a perspective view of a semiconductor structure of the SRAM bit-cell 10b shown in FIG. 2B in accordance with some embodiments of the present disclosure. FIG. 3C illustrates an enlarge view of a region Cl in FIG. 3B in accordance with some embodiments of the present disclosure. FIG. 4B illustrates a layout of a semiconductor structure in top tier in accordance with some embodiments of the present disclosure. FIGS. 5-7, 8B, 9B, and 10B illustrate cross-sectional views obtained from reference cross-sections B1-B1′, B2-B2′, B3-B3′, B4-B4′, B5-B5′, B6-B6′, in FIG. 3B. While FIG. 3B illustrates embodiments of the SRAM bit-cell 10b with a configuration than the SRAM bit-cell 10a in FIG. 3A, the present disclosure may repeat reference numerals and/or letters in the various examples. This repetition is for the purpose of simplicity and clarity and does not in itself dictate a relationship between the various embodiments and/or configurations discussed.

Specifically, the SRAM bit-cells 10a and 10b have the same three-tier transistor layout and power connectivity but differ in their approach to data access and control. The pull-up transistors PU_{R} and PU_{L} of SRAM bit-cell 10b are situated in the bottom tier, and these transistors are connected to the voltage source line VDD and responsible for setting the storage nodes to a high state. The pull-down transistors PD_{R} and PD_{L} are situated in the middle tier and connected to ground lines VSS-1 and VSS-2, and these transistors pull the storage nodes to a low state. The pass-gate transistors PG_{R1}, PG_{R2}, PG_{L1}, and PG_{L2} are situated in the top tier, and these transistors control access to the storage nodes, QB and Q, and play a role in reading and writing operations.

Unlike in the SRAM bit-cell 10a, where pass-gate transistors are connected to a common pair of bit lines (e.g., bit lines BL and BLB), the SRAM bit-cell 10b may feature a dual-port configuration. The SRAM bit-cell 10b can have a first pair of pass-gate transistors PG_{L1} and PG_{L2} connected to separate bit lines, with the pass-gate transistors PG_{L1} connected to the bit line BL₁ and the pass-gate transistors PG_{L2} connected to the bit line BL₂. This can allow for individual control and access to different parts of the SRAM bit-cell 10a, facilitating separate operations or enhancing parallel processing capabilities. The SRAM bit-cell 10b can further have a second pair of pass-gate transistors PG_{R1} and PG_{R2} connected to separate bit lines, with the pass-gate transistors PG_{L2} connected to the bit line BLB₁ and the pass-gate transistors PG_{R2} connected to the bit line BLB₂, mirroring the functionality of the first pair but on complementary bit lines (e.g., bit lines BLB₁ and BLB₂).

Additionally, each pair of pass-gate transistors PG_{L1}, PG_{L2}, PG_{R1}, and PG_{R2} can be connected to different word lines WL₁ and WL₂, unlike in SRAM bit-cell 10a where all pass-gate transistors are connected to a single word line (WL. This setup in SRAM bit-cell 10b can allow each pair of transistors to operate independently, supporting dual-port functionality that can increase the flexibility and efficiency of the SRAM cell in multi-threaded environments. The ability of SRAM bit-cell 10b to connect each pair of pass-gate transistors to separate word lines and bit lines effectively doubles the access paths into the cell, enhancing its capability to perform simultaneous read/write operations or handle two separate processes at the same time.

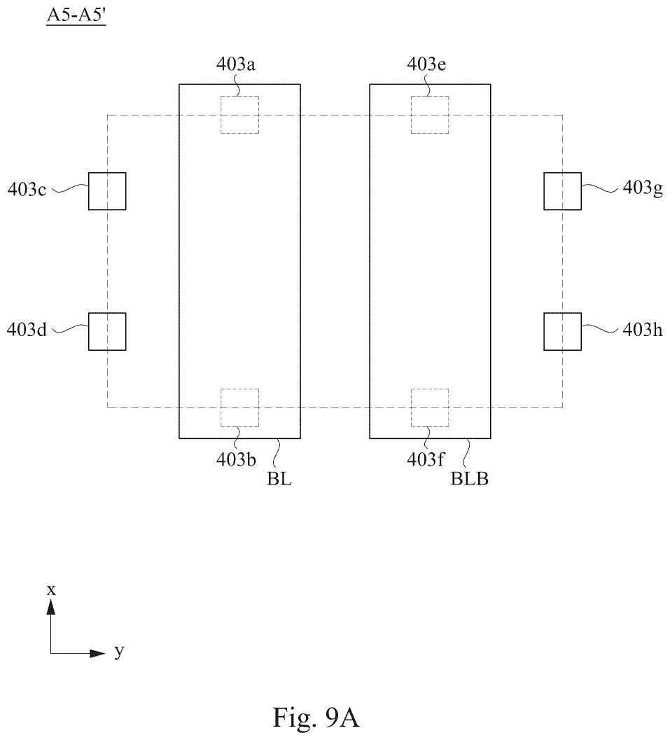

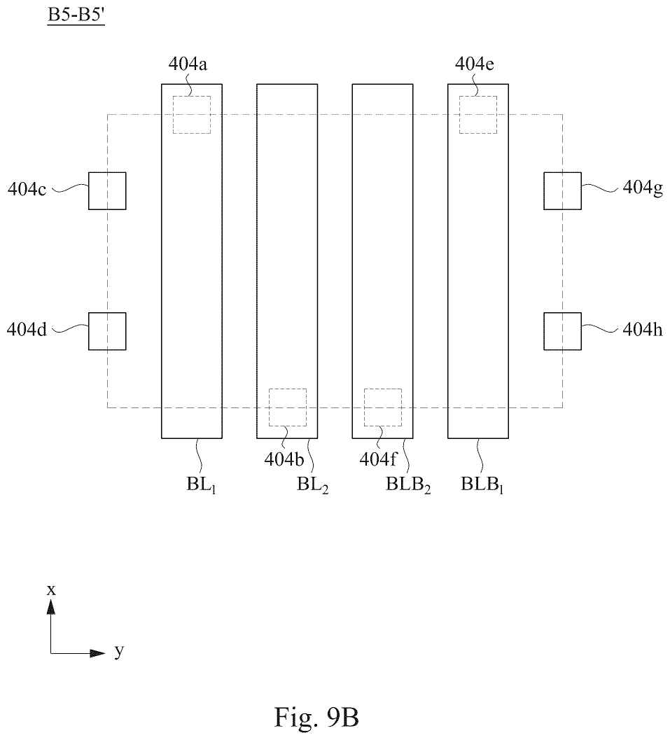

With regard to the transistors PG_{L1}, PG_{L2}, PG_{R1}, and PG_{R2} in the top-tier as shown in FIGS. 3B, 4B, 8B, 9B, and 10B, an non-sharing source/drain region 308 of the transistor PG_{L1} is electrically connected to the overlying bit line BL₁ through contacts 404a (see FIGS. 8B and 9B), and an non-sharing source/drain region 308 of the transistor PG_{L2} is electrically connected to the overlying bit line BL₂ through contacts 404b. The gate structure G3 of the transistor PG_{L1} is electrically connected to the overlying word line WL₁ through the contact 404c, and the gate structure G3 of the transistor PG_{L2} is electrically connected to the overlying word line WL₂ through the contact 404d. Similarly, an non-sharing source/drain region 308 of the transistor PG_{R 1} is electrically connected to the overlying bit line BLB₁ through contacts 404e (see FIGS. 8B and 9B), and an non-sharing source/drain region 308 of the transistor PG_{R2} is electrically connected to the overlying bit line BLB₂ through contacts 404f. The gate structure G3 of the transistor PG_{R 1} is electrically connected to the overlying word line WL₁ through the contact 404g, and the gate structure G3 of the transistor PG_{R2} is electrically connected to the overlying word line WL₂ through the contact 404h. In some embodiments, the bit line BL₁, BL₂, BLB₁, and BLB₂ can be formed in a first metal layer M1 at a higher elevation than the transistors PG_{L1}, PG_{L2}, PG_{R1}, and PG_{R2}. The word lines WL₁ and WL₂ can be formed in a second metal layer M2 at a higher elevation than the first metal layer M1.

In some embodiments, the fabrication process for both the read-enhanced and dual-port SRAM bit-cells 10a and 10b can be unified in their approach, utilizing a sequential (epitaxial three dimension) process for constructing a 3-tier high-density (HD) SRAM architecture. This sequential process flow can continues up to the fabrication of the top-tier transistors. This standardized approach in the initial stages of manufacturing can ensure efficiency and consistency in the production of the integrated circuit structures, before diverging at the final stages to accommodate the specific needs of the top tier transistors in each SRAM bit-cell design.

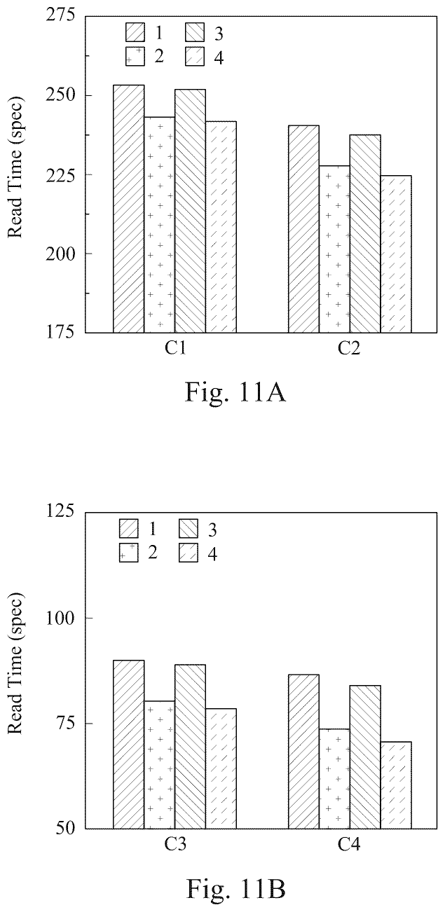

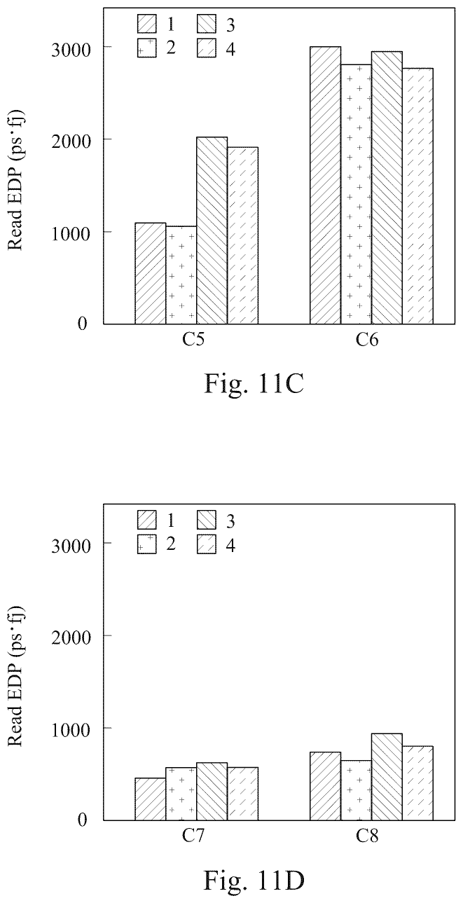

Reference is made to FIGS. 11A and 11B. FIGS. 11A and 11B show a comparative analysis of read times between two types of SRAM bit-cells (e.g., 6T SRAM bit-cells and 8T bit-cells 10a shown in FIG. 2A) across four different positions (e.g., portions 1, 2, 3, and 4 shown in FIG. 1) within an SRAM array. The 6T SRAM bit-cell can consist of a three-tier setup with one pair of pass-gate transistors at the top, one pair of pull-down transistors in the middle, and one pair of pull-up transistors at the bottom, and the transistor ratio (e.g., pull-down: pull-up: pass-gate) can be 1:1:1. These figures can reveal the impact of voltage differences on bit lines BL and BLB and the associated read times in the SRAM bit-cells. Additionally, FIG. 11A shows the data corresponding to a condition where the voltage difference between bit lines BL and BLB is about 100 mV, and FIG. 11B shows the data corresponding to a condition where the voltage difference between bit lines BL and BLB is about 30 mV. In FIGS. 11A and 11B, datasets C1 and C3 represent the read times for the 6T SRAM bit-cells, and datasets C2 and C4 represent the read times for the 8T SRAM bit-cells 10a as shown in FIG. 2A.

As shown in FIG. 11A, when the voltage difference is about 100 mV, the 8T SRAM bit-cells 10a consistently show improved read times across all positions compared to the 6T bit-cells. Specifically, in the position 1, the read time for the 8T bit-cell is 3-10% faster than the 6T bit-cell, such as 3, 4, 5, 5.3, 6, 7, 8, 9, or 10%. In position 4 the read time for the 8T bit-cell is 3-10% faster than the 6T bit-cell, 5, 6, 7, 7.6, 8, 9, 10, 11, 12, 13, 14, or 15%.

As shown in FIG. 11B, with a reduced voltage difference of 30 mV, the 8T SRAM bit-cells 10a still show improved read times compared to the 6T bit-cells at corresponding positions. Specifically, in the position 1, the read time for the 8T bit-cell is 2-8% faster than the 6T bit-cell, such as 2, 3, 3.6, 4, 5, 5.3, 6, 7, or 8%. In position 4 the read time for the 8T bit-cell is 3-10% faster than the 6T bit-cell, 5, 6, 7, 7.6, 8, 9, 10, 10.6, 11, 12, 13, 14, 15, 16, 17, 18, 19, or 20%.

Therefore, the 8T SRAM bit-cells 10a can demonstrate consistently better performance in read times compared to the 6T bit-cells, which can be attributed to the stronger pass-gate transistors used in the 8T bit-cell configuration. The 8T bit-cell can enhance the discharging rate of the bit lines BL and BLB, thus facilitating faster read operations. Additionally, FIGS. 11A and 11B show that the 8T SRAM bit-cells are not only faster but also more efficient in handling larger voltage swings. The variability in improvement across different positions can indicate that while the 8T SRAM bit-cells 10a provide an overall enhancement in read times, factors such as proximity to peripheral components like sensing amplifiers 5 and word line drivers 6 (see FIG. 1) might influence the extent of improvement.

FIGS. 11C and 11D show a comparative analysis of read energy delay products (EDP) between two types of SRAM bit-cells (e.g., 6T bit-cells and 8T bit-cells 10a shown in FIG. 2A) across four different positions (e.g., portions 1, 2, 3, and 4 shown in FIG. 1) within an SRAM array. These figures can reveal the impact of voltage differences on bit lines BL and BLB and the associated read energy delay products in the SRAM bit-cells. Additionally, FIG. 11C shows the data corresponding to a condition where the voltage difference between bit lines BL and BLB is about 100 mV, and FIG. 11D shows the data corresponding to a condition where the voltage difference between bit lines BL and BLB is about 30 mV. In FIGS. 11A and 11B, datasets C5 and C7 represent the read energy delay products s for the 6T SRAM bit-cells, and datasets C6 and C8 represent the read energy delay products for the 8T SRAM bit-cells 10a as shown in FIG. 2A.

As shown in FIG. 11C, when the voltage difference is about 100 mV, the 8T SRAM bit-cells 10a consistently show greater read energy delay products across all positions compared to the 6T bit-cells. As shown in FIG. 11D, with a reduced voltage difference of 30 mV, the 8T SRAM bit-cells 10a still show greater read energy delay products compared to the 6T bit-cells at corresponding positions. When the voltage difference between the bit lines decreases from 100 mV to 30 mV, the 8T SRAM bit-cells 10a exhibit a greater reduction in energy delay product compared to the 6T bit-cells, indicating that the 8T SRAM bit-cells 10a can be more sensitive to changes in voltage difference, possibly due to their enhanced pass-gate and discharge mechanisms. By way of example and not limitation, the 6T SRAM bit-cells can have a reduction in energy delay product, ranging from about 40-60%, such as about 40, 45, 47, 50, 55, or 60%. The 8T SRAM bit-cells 10a can have a more reduction in energy delay product, ranging from 70-90%, such as about 70, 75, 77, 80, 85, or 90%. In some embodiments, at a lower voltage difference (e.g., 30 mV), the energy delay product of the 8T SRAM bit-cell 10a can be only about 10-15%, such as about 10, 11, 12, 13, 14, or 15%, higher than that of the 6T SRAM bit-cell. This closer performance at reduced voltage differences can indicate that the 8T SRAM bit-cell 10a can be more effective or comparable under lower stress conditions on the bit lines. In some embodiments, the calculations of energy delay product include factors such as word line activation, discharging, and recharging of the bit lines to the supply voltage Vdd.

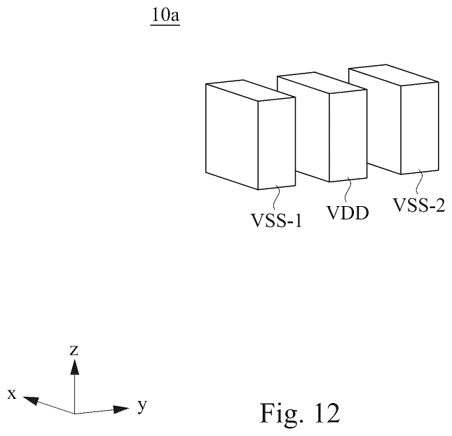

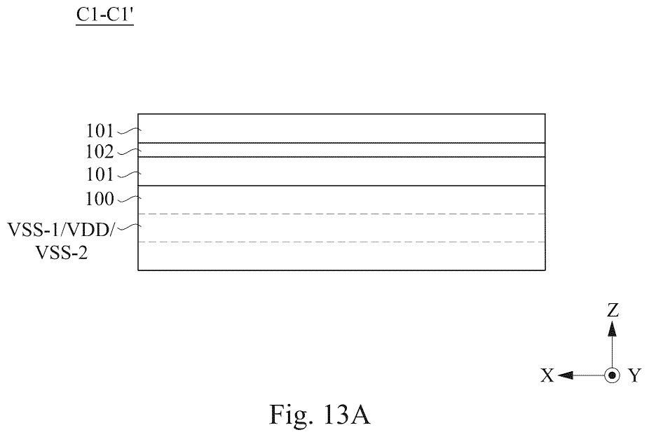

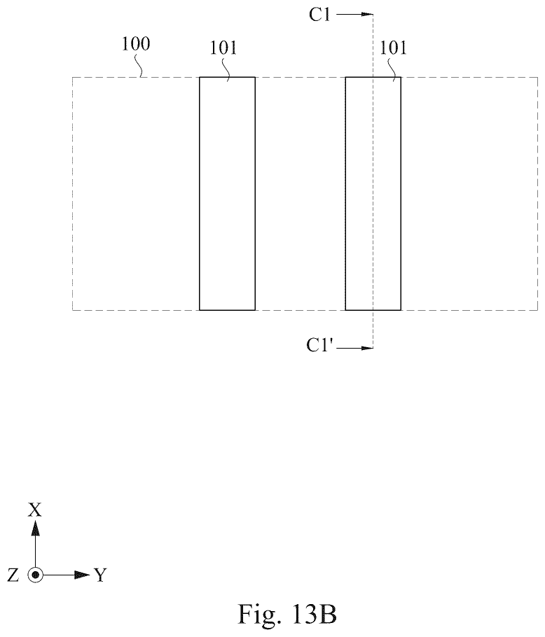

Reference is made to FIGS. 12-55B. FIGS. 12-55B illustrate schematic views of intermediate stages in the formation of a semiconductor structure in accordance with some embodiments of the present disclosure. Specifically, FIGS. 12, 26, 27A, 40A, 41A, 54A, and 55A illustrate perspective views of the formation of the semiconductor structure in accordance with some embodiments. FIGS. 13A, 14-25, 27B, 28A, 29-39, 40B, 41B, 42B-53, 54B, and 55B illustrate cross-sectional views obtained from the reference cross-section C1-C1′ in the formation of the semiconductor structure in accordance with some embodiments. FIGS. 13B, 28B, 42A illustrate top views of the formation of the semiconductor structure in accordance with some embodiments. It is understood that additional operations can be provided before, during, and after the processes shown by FIGS. 12-55B, and some of the operations described below can be replaced or eliminated, for additional embodiments of the method. The order of the operations/processes may be interchangeable.

Reference is made to FIGS. 12-13B. An epitaxial stack is formed over a substrate 100 as shown in FIG. 12. In some embodiments, the substrate 100 may include silicon (Si). Alternatively, the substrate 100 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 100 may include a semiconductor-on-insulator (SOI) structure such as a buried dielectric layer. Also alternatively, the substrate 100 may include a buried dielectric layer such as a buried oxide (BOX) layer, such as that formed by a method referred to as separation by implantation of oxygen (SIMOX) technology, wafer bonding, SEG, or another appropriate method. The substrate 100 may include buried metals. The buried metal can include voltage source line VDD and ground lines VSS-1 and VSS-2. In some embodiments, the buried metal can include power via, backside contacts, self-aligned front-to-back via, etc. In some embodiments, the voltage source line VDD and the ground lines VSS-1 and VSS-2 may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, other suitable materials, or combinations thereof, and the formation thereof can be performed by any suitable process. The ground lines VSS-1 and VSS-2 and the voltage source line VDD can be formed at a same level height.

As shown in FIGS. 13A and 13B, the epitaxial stack includes sacrificial layers 101 of a first composition interposed by a channel layer 102 of a second composition. The first and second compositions can be different. In some embodiments, the sacrificial layers 101 may be made of SiGe and have a different germanium atomic concentration than the channel layer 102. In some embodiments, the sacrificial layer 101 can have a greater germanium atomic concentration than the channel layer 102. In some embodiments, the channel layer 102 may be made of silicon (Si). By way of example but not limitation, the sacrificial layer 101 may have a germanium atomic concentration in a range from about 10 to 90%, such as about 10, 20, 30, 40, 50, 60, 70, 80, 90%. However, other embodiments are possible including those that provide for the first and second compositions having different etch selectivity.

The use of the channel layer 102 to define a channel or channels of a device is further discussed below. It is noted that one layer of the channel layer 102 is arranged as illustrated in FIG. 13A, which is for illustrative purposes only and not intended to be limiting beyond what is specifically recited in the claims. It can be appreciated that any number of sacrificial layers 101 can be formed in the epitaxial stack; the number of layers depending on the desired number of channels regions for the transistor. In some embodiments, the number of the channel layer 102 can be between about 1 and 101, such as 1, 10, 15, 20, 25, 30, 35, 40, 45, 50, 55, 60, 65, 70, 75, 80, 85, 90, 95, 100, or 101. As described in more detail below, the channel layer 102 may serve as a channel region for a subsequently-formed semiconductor device and the thickness is chosen based on device performance considerations. By way of example and not limitation, the thickness of the channel layer 102 can be in a range from about 0.5 to 50 nm, such as about 0.5, 1, 5, 10, 15, 20, 25, 30, 35, 40, 45, or 50 nm. In some embodiments, the length of the channel layer 102 can be in a range from 5 to 500 nm, such as about 5, 50, 100, 150, 200, 250, 300, 350, 400, 450, or 500 nm. In some embodiments, the channel layer 102 can have square/rectangle/diamond cross-sectional profile taken along the lengthwise direction of the gate structure. The sacrificial layers 101 in the channel region may eventually be removed and serve to define a vertical distance between adjacent channel region(s) for a subsequently-formed multi-gate device and the thickness is chosen based on device performance considerations. In some embodiment, the thickness of the sacrificial layer 101 can be in a range from about 5 to 100 nm, such as about 5, 10, 20, 30, 40, 50, 60, 70, 80, 90, or 100 nm.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the channel layer 102 can include the same material as the substrate 100. In some embodiments, the sacrificial layers 101 and channel layer 102 can include different materials than the substrate 100. As stated above, in at least some examples, the sacrificial layers 101 can include epitaxially grown silicon germanium (SiGe) layers, and the channel layers 102 can include an epitaxially grown silicon (Si) layer. Alternatively, in some embodiments, either of the sacrificial layer 101 and the channel layer 102 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. In some embodiments, the channel layer 102 can include IV-based material, such as Si, Ge, Sn, Si₁₋ₓGeₓ, Ge_{1-y}Sn_{y}, Si_{1-x-y}GeₓSn_{y}, other suitable materials, or combinations thereof. In some embodiments, the channel layer 102 can include III-V-based material, an oxide semiconductor material, 2D (two dimensional) material, other suitable materials, or combinations thereof. As discussed, the materials of the sacrificial layer 101 and the channel layer 102 may be chosen based on providing differing oxidation and/or etching selectivity properties.

Subsequently, the epitaxial stack includes the channel layer 102 and the sacrificial layers 101 can be patterned, such that the channel layer 102 and the sacrificial layers 101 or portions thereof may be formed nanostructures as shown in FIG. 13B. Specifically, the channel layer 102 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layer 102 and the sacrificial layers 101 may be fabricated using suitable processes including double-patterning or multi-patterning processes.

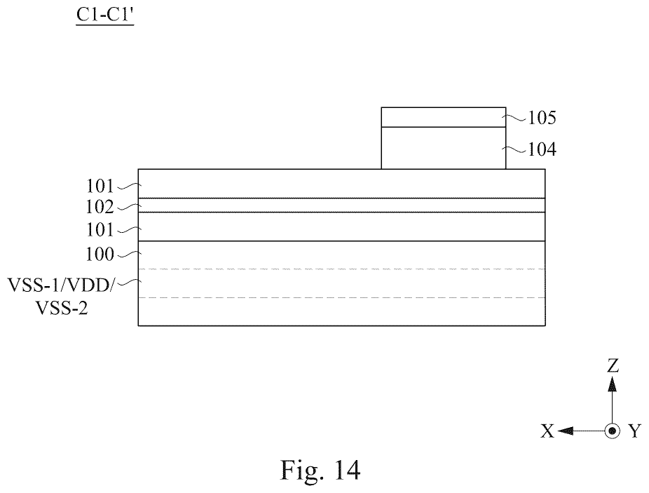

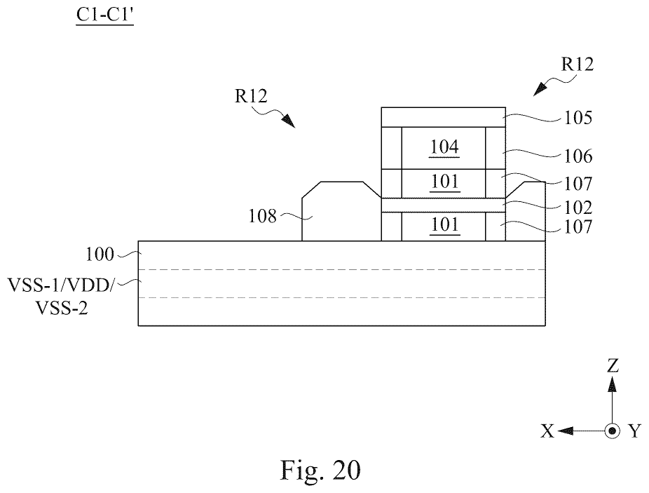

Reference is made to FIG. 14. Dummy gate layers 104 and hard mask layers 105 can be formed over the epitaxial stack as shown in FIGS. 13A and 13B. Portions of the channel layer 102 underlying the dummy gate layers 104 may be referred to as the channel regions. The dummy gate layer 104 may also define source/drain regions 108 (labeled in FIG. 20). Dummy gate formation operation forms the dummy gate layer 104 and the hard mask layer 105 over the dummy gate layer 104. The hard mask layer 105 is then patterned, followed by patterning the dummy gate layer 104 by using the patterned hard mask layer 105 as an etch mask. The etch process may include a wet etch, a dry etch, and/or combinations thereof.

In some embodiments, the dummy gate layer 104 may include polycrystalline-silicon (poly-Si), poly-crystalline silicon-germanium (poly-SiGe), metallic nitrides, metallic silicides, metallic oxides, or metals. In some embodiments, the dummy gate layer 104 may include a metal-containing material such as TIN, TaN, TaC, Co, Ru, Al, combinations thereof, or multi-layers thereof. The hard mask layer 105 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 104 may be deposited by CVD, physical vapor deposition (PVD), sputter deposition, or other techniques suitable for depositing conductive materials. In some embodiments, the hard mask layer 105 may be deposited by CVD, physical vapor deposition (PVD), sputter deposition, or other techniques suitable for depositing conductive materials. In some embodiments, the dummy gate layer 104 can be interchangeably referred to a dummy gate, a dummy gate pattern, a dummy gate strip, an isolation structure, or a dielectric gate.

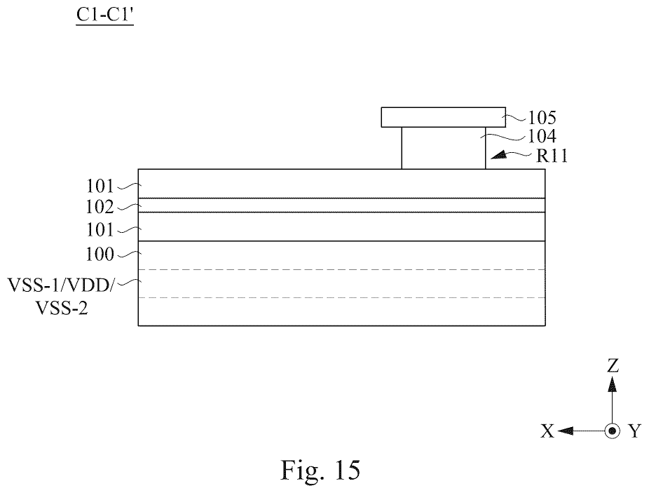

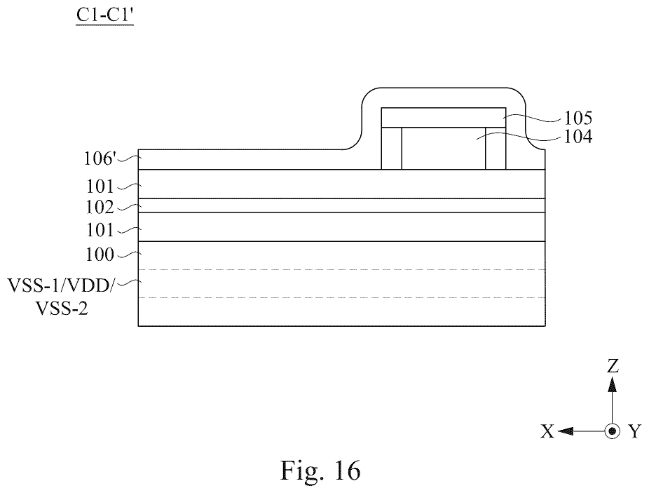

Reference is made to FIG. 15. The dummy gate layer 104 is laterally or horizontally recessed by using suitable etch techniques, resulting in lateral recesses R11 vertically between the sacrificial layer 101 and the hard mask layer 105. This operation may be performed by using a selective etching process. By way of example and not limitation, the sacrificial layer 101 may be made of SiGe, the hard mask layer 105 may be made of a dielectric material and the dummy gate layer 104 may be made of silicon allowing for the selective etching of the dummy gate layer 104. In some embodiments, the selective dry etching etches Si at a faster etch rate than it etches SiGe and the dielectric material. As a result, the sacrificial layer 101 and the hard mask layer 105 laterally extend past opposite end surfaces of the dummy gate layer 104.

Reference is made to FIG. 16. After recession of the dummy gate layer 104 is completed, a spacer material 106′ is deposited over the substrate 100. The spacer material 106′ may be a conformal layer on the topmost sacrificial layer 101, the dummy gate layers 104, and the hard mask layers 105. The spacer material 106′ may include a dielectric material such as silicon oxide, silicon nitride, silicon carbide, silicon oxynitride, SiCN films, silicon oxycarbide, SiOCN films, and/or combinations thereof. In some embodiments, the spacer material 106′ can include multiple layers, such as a first spacer layer and a second spacer layer formed over the first spacer layer. By way of example, the spacer material 106′ may be formed by depositing a dielectric material over the topmost sacrificial layer 101, the dummy gate layers 104, and the hard mask layers 105 using suitable deposition processes.

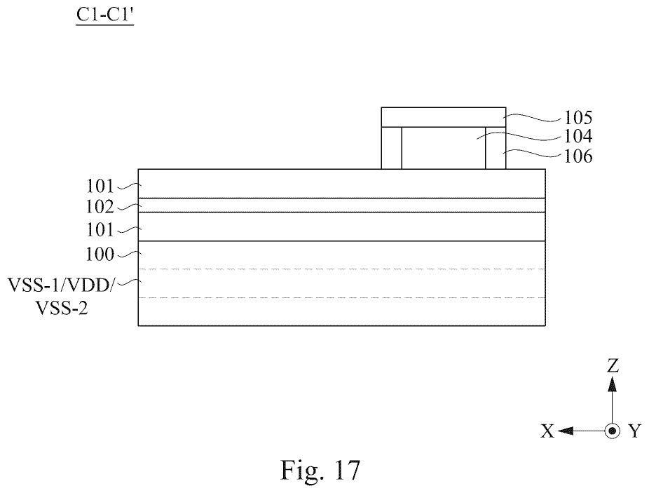

Reference is made to FIG. 17. An anisotropic etching process is then performed on the deposited spacer material 106′ to expose the topmost sacrificial layer 101 and the hard mask layers 105. Portions of the spacer material 106′ directly on the hard mask layers 105 and on the topmost sacrificial layer 101 not covered by the hard mask layers 105 may be completely removed by this anisotropic etching process. Portions of the spacer material 106′ on sidewalls of the recessed dummy gate layer 104 may remain in the lateral recesses R11, forming gate sidewall spacers 106, which are denoted as the gate spacers 106. In some embodiments, a lateral dimension (or thickness) of the sidewall spacer 106 can be in a range from about 1 to 25 nm, such as about 1, 2, 4, 6, 8, 10, 12, 14, 16, 18, 20, 22, 24, or 25 nm.

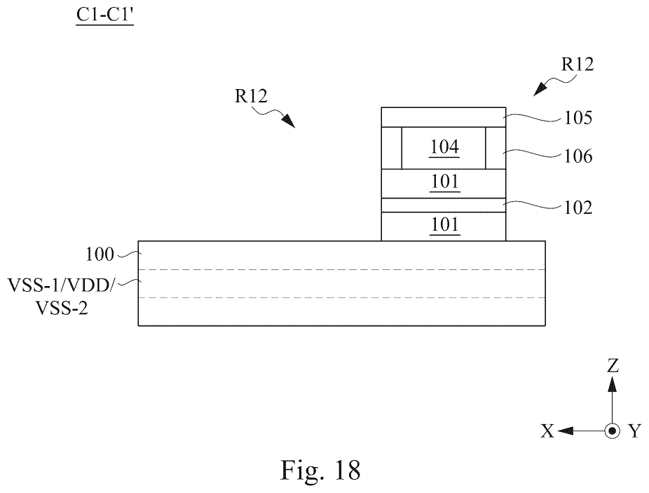

Reference is made to FIG. 18. Exposed portions of the patterned channel layer 102 and the patterned sacrificial layers 101 that extend laterally beyond the gate spacers 106 are etched by using, for example, an anisotropic etching process that uses the dummy gate layer 104 and the gate spacers 106 as an etch mask, resulting in recesses R12 into the channel layers 102 and the sacrificial layers 101. After the anisotropic etching, end surfaces of the patterned channel layer 102 and the patterned sacrificial layers 101 and respective outermost sidewalls of the gate spacers 106 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

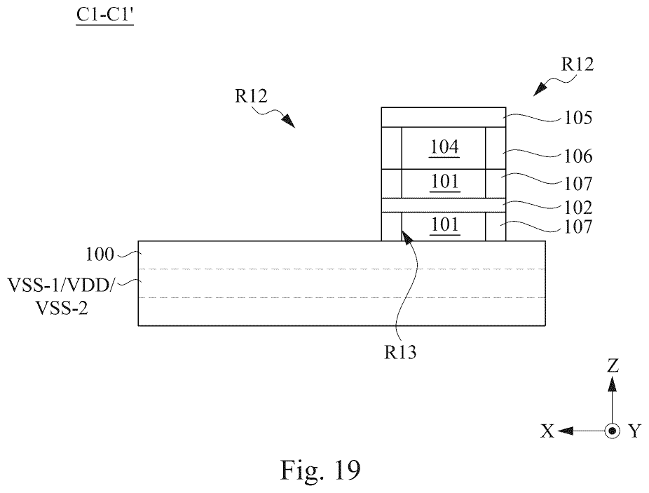

Reference is made to FIG. 19. The patterned sacrificial layers 101 are laterally or horizontally recessed by using suitable etch techniques, resulting in lateral recesses R13. This operation may be performed by using a selective etching process. By way of example and not limitation, the sacrificial layers 101 can be made of SiGe and the channel layer 102 can be made of silicon allowing for the selective etching of the sacrificial layers 101. In some embodiments, the selective dry etching etches SiGe at a faster etch rate than it etches Si. As a result, the patterned channel layer 102 laterally extends past opposite end surfaces of the patterned sacrificial layers 101.

Subsequently, inner spacers 107 are filled in the recesses R13, respectively. For example, spacer material layers are formed to fill the recesses R13 left by the lateral etching of the sacrificial layers 101 discussed above. The spacer material layer may be a low-k dielectric material, such as SiO₂, SiN, SiC, SION, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R13 left by the lateral etching of the sacrificial layers 101 are left. After the trimming process, the remaining portions of the deposited spacer material are denoted as inner spacers 107 in the recesses R13. The inner spacers 107 serve to isolate metal gates from source/drain regions formed in subsequent processing.

Reference is made to FIG. 20. Source/drain regions 108 are formed in the recesses R12 and connected to the channel layer 102. The source/drain regions 108 may be formed by performing an epitaxial growth process that provides an epitaxial material on the substrate 100. During the epitaxial growth process, the dummy gate layer 104, the gate spacers 106, and the inner spacers 107 limit the source/drain regions 108 to the substrate 100 and the channel layer 102. In some embodiments, the lattice constants of the source/drain regions 108 are different from the lattice constant of the channel layer 102, so that the channel layer 102 can be strained or stressed by the source/drain regions 108 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 102.

In some embodiments, the source/drain regions 108 may include Ge, Si, GaAs, AlGaAs, SiGe, GaAsP, SiP, or other suitable material. The source/drain regions 108 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 108 are not in-situ doped, an implantation process (i.e., a junction implant process) is performed to dope the source/drain regions 108. In some embodiments, the source/drain regions 208 can be of a p-type transistor and include SiGeB and/or GeSnB.

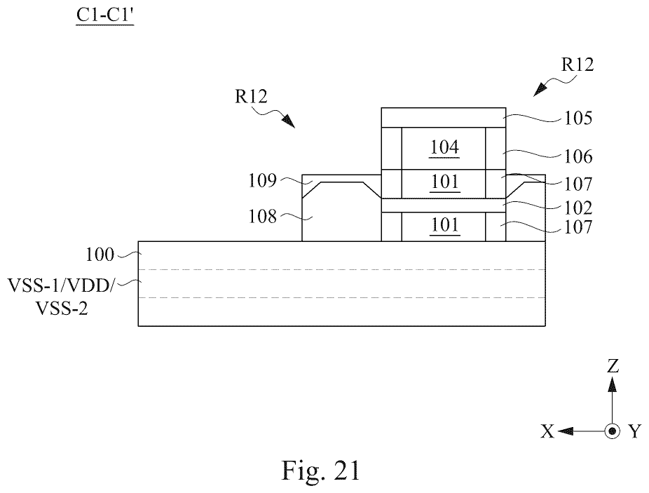

Reference is made to FIG. 21. Source/drain contacts 109 can be formed over the source/drain regions 108. In some embodiments, the source/drain contacts 109 may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, other suitable materials, or combinations thereof. In some embodiments, the formation of the source/drain contacts 109 can be performed by such as a lift-off process. By way of example and not limitation, a mask layer (not shown) can be formed by depositing a photoresist layer over the substrate 100 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 109. Subsequently, a contact material can be deposited over the substrate 100 and formed on the source/drain contacts 109 and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 108 are remained to form the source/drain contacts 109.

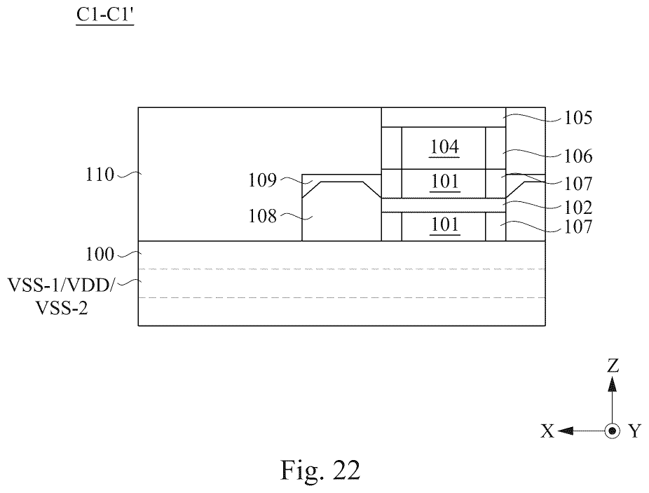

Reference is made to FIG. 22. An ILD layer 110 is formed over the substrate 100. In some embodiments, the ILD layer 110 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 110 may be deposited by a plasma-enhanced chemical vapor deposition (PECVD) process or other suitable deposition technique. In some embodiments, after formation of the ILD layer 110, the substrate 100 may be subject to a high thermal budget process to anneal the ILD layer 110. Subsequently, a planarization process (e.g., CMP) is performed to remove the excessive ILD layer 110 until the hard mask layer 105 is exposed. In some embodiments, the hard mask layer 105 may also act as an etch stop layer for etching the ILD layer 110.

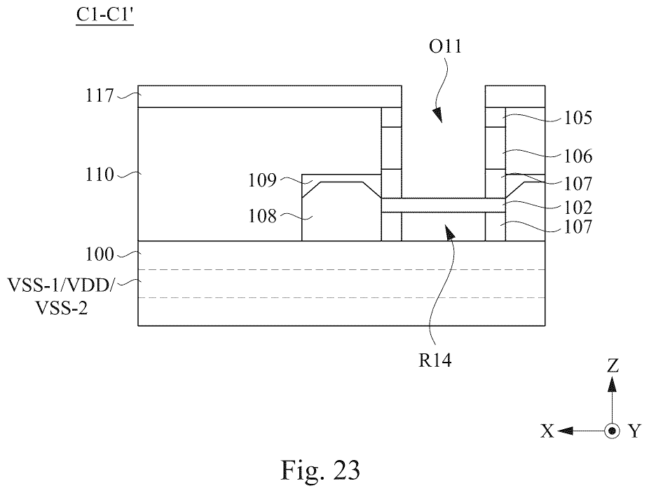

Reference is made to FIG. 23. A hard mask layer 117 may be formed over the ILD layer 110 and the hard mask layer 105. In some embodiments, the hard mask layer 117 may be made of the same material as the ILD layer 110, thereby resulting in a substantially indistinguishable interface between the hard mask layer 117 and the ILD layer 110. In some embodiments, the hard mask layer 117 may be made of a different material than the ILD layer 110b. In some embodiments, the hard mask layer 117 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 117 can be performed by using any suitable method, such as CVD, physical vapor deposition (PVD), ALD, PEALD, PECVD, SACVD, FCVD, spin-on, and/or the like, or a combination thereof. Subsequently, the hard mask layer 117 is patterned and then be used to etch the dummy gate layer 104 (see FIG. 22), the hard mask layer 105, and the ILD layers 110. The hard mask layer 117 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 117, the dummy gate layer 104 (see FIG. 22), the hard mask layer 105, and the ILD layer 110 can be etched through the patterned hard mask layer 117 to form an opening O11. The opening O11 can expose a sidewall of the epitaxial stack, such that the channel layer 102 and the sacrificial layers 101 can be exposed from the opening O11. The etching process may include dry etching, wet etching, and/or other etching methods (e.g., reactive ion etching). In some embodiments, the opening O11 may have a rectangular profile extending along Y-direction from the top view. After the formation of the opening O11, the patterned mask can be removed by a suitable technique, such as a wet clean process, an ashing process, or the like.

The sacrificial layers 101 (see FIG. 23) are removed in one or more etching process, so that a recess R14 can be formed to inherit the shape of a lower one of the sacrificial layers 101. The recess R14 can expose a bottom surface of the channel layer 102, and the opening O11 can expose a top surface of the channel layer 102. In some embodiments, the sacrificial layers 101 can be removed by an anisotropic dry etch process. For example, the etching process may include a dry etch process using reaction gas(es) that selectively etch the sacrificial layers 101 at faster rates than the substrate 100, the ILD layer 110, and the channel layer 102.

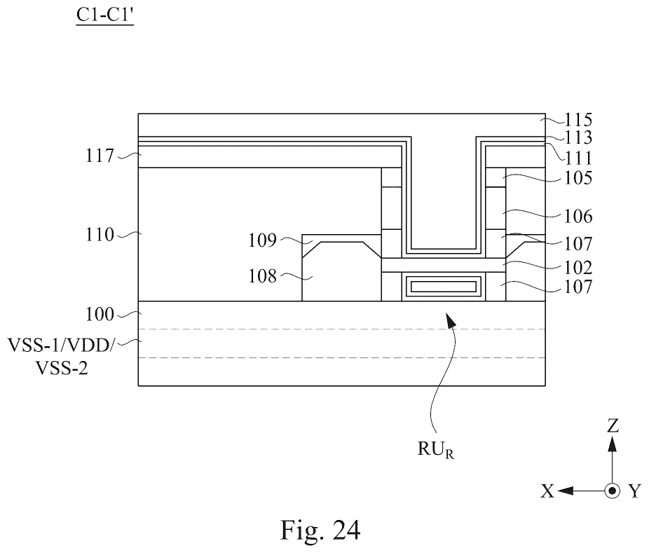

Reference is made to FIG. 24. An interfacial layer 111 and a high-k dielectric layer 113 can be conformally formed over the hard mask layer 117 and in the opening O11 and the recesses R14. In some embodiments, the interfacial layer 111 may include a dielectric material such as silicon oxide (SiO₂), HfSiO, or silicon oxynitride (SiON). In some embodiments, the interfacial layer 111 may be deposited using any suitable method, such as CVD, physical vapor deposition (PVD), ALD, PEALD, PECVD, SACVD, FCVD, spin-on, and/or the like, or a combination thereof. In some embodiments, the high-k dielectric layer 113 may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 113 may be deposited using any suitable method, such as CVD, physical vapor deposition (PVD), ALD, PEALD, PECVD, SACVD, FCVD, spin-on, and/or the like, or a combination thereof.

Subsequently, a gate electrode layer 115 can be deposited over the high-k dielectric layer 113. The gate electrode layer 115 may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, or other suitable materials.

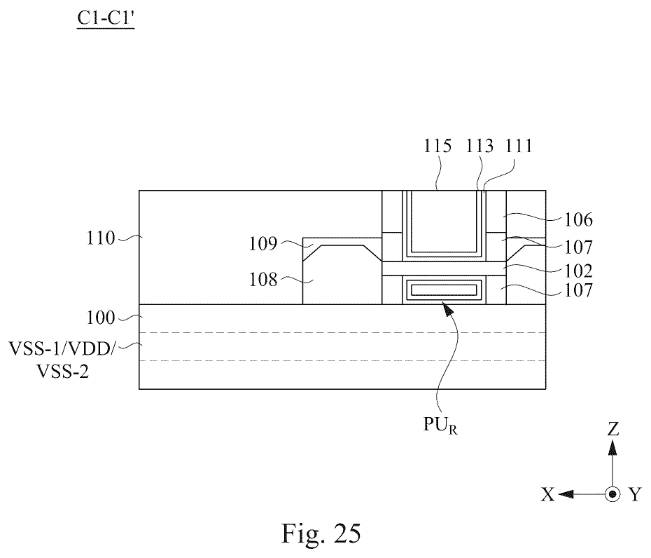

Reference is made to FIG. 25. A planarization process (e.g., CMP) is performed to remove the excessive gate electrode layer 115, the high-k dielectric layer 113, the interfacial layer 111, and the hard mask layers 105 and 117 above the gate spacers 106. The gate spacers 106 may also act as an etch stop layer for etching the gate electrode layer 115, the high-k dielectric layer 113, the interfacial layer 111, and the hard mask layers 105 and 117. Therefore, a (metal) gate structure G1 including the gate electrode layer 115, the high-k dielectric layer 113, and the interfacial layer 111 can be formed in the recesses R14 to surround the channel layer 102 suspended in the recesses R14. In some embodiments, the gate structure G1 may be the final gate of a GAA FET. Therefore, the semiconductor structure can include transistors PU_{R}, and PU_{L} (see FIGS. 3A and 25). The transistors PU_{R} and PU_{L} each can include the channel layer 102, the gate structure G1 wrapping around the channel layer 102, and the source/drain regions 108 on opposite sides of the gate structure G1 and connected to the channel layer 102. In some embodiments, the transistors PU_{R} and PU_{L} can be interchangeably referred to as bottom-tier transistors.

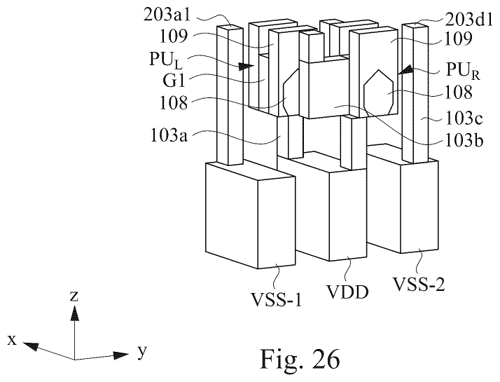

Reference is made to FIG. 26. The contact 203al can be formed to pass through the ILD layer 110 and connect the first one of the source/drain regions 208 of the transistor PD_{L} (see FIG. 3A) to the underlying ground line VSS-1. The contact 203dl can be formed to pass through the ILD layer 110 and connect the first one of the source/drain regions 208 of the transistor PD_{R} (see FIG. 3A) to the underlying ground line VSS-2. In some embodiments, the contacts 203al and 203dl may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, other suitable materials, or combinations thereof, and the formation thereof can be performed by any suitable process.

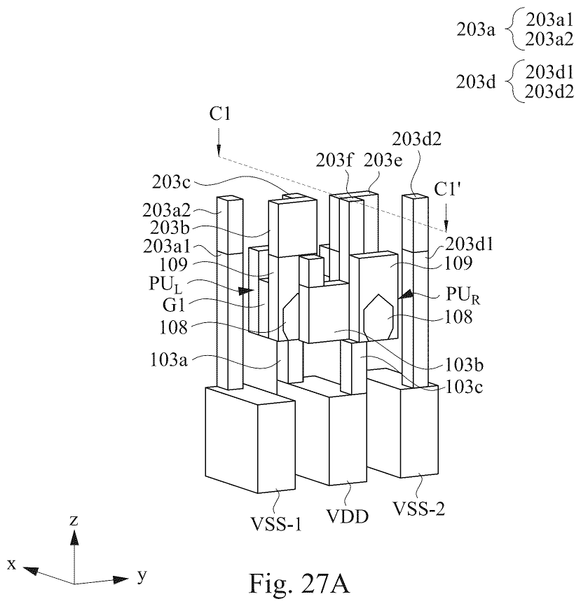

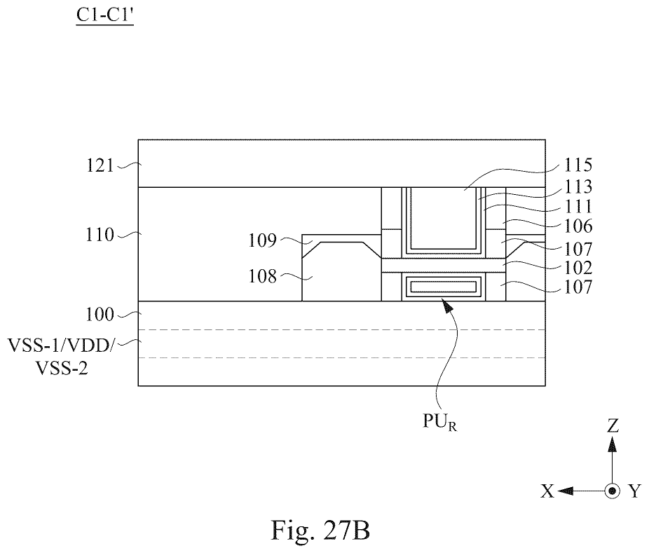

Reference is made to FIGS. 27A and 27B. A MEOL layer 121 can be formed over the transistors PU_{R} and PU_{L}. The MEOL layer 121 may include an inter-metal dielectric and conductive interconnect to connect the transistors PU_{R} and PU_{L} to the overlying features (e.g., transistors PG_{R1}, PG_{L2}, PG_{R1}, PG_{L2}, PD_{R}, and PD_{L}). In some embodiments, the inter-metal dielectric may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

In some embodiments, the conductive interconnect formed in the inter-metal dielectric may include the contacts 203a2, 203d2, 203b, 203e, 203c, and 203f. The contact 203a2 can be formed to land on the contact 203al, and the contact 203d2 is formed to land on the contact 203dl. In some embodiments, the contacts 203al and 203a2 can be collectively referred to the contact 203a as shown in FIG. 3A, and the contacts 203dl and 203d2 can be collectively referred to the contact 203d as shown in FIG. 3A. The contact 203b can be formed on the source/drain contact 109 over the source/drain region 208 of the transistor PU_{L}, and the contact 203e can be formed on the source/drain contact 109 over the source/drain region 208 of the transistor PU_{R}. The contact 203c (see FIG. 6) can be formed on the gate structure G1 of the underlying transistor PU_{L}, and the contact 203f (see FIG. 6) can be formed on the gate structure G1 of the underlying transistor PU_{R}. In some embodiments, the conductive interconnect can be made of tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, or other suitable materials.

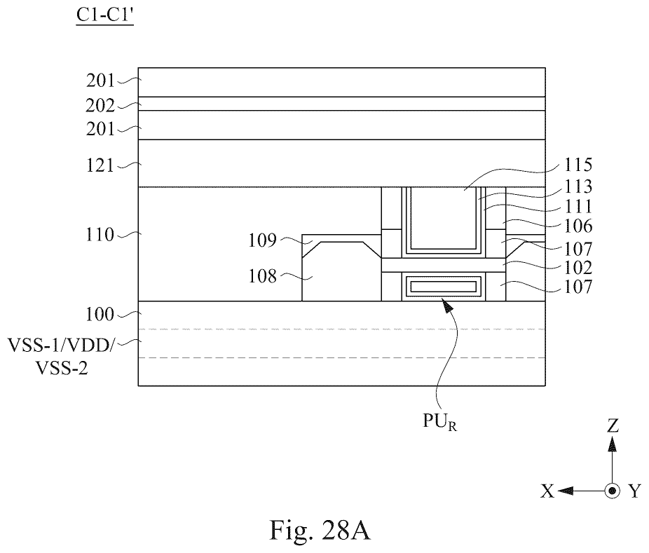

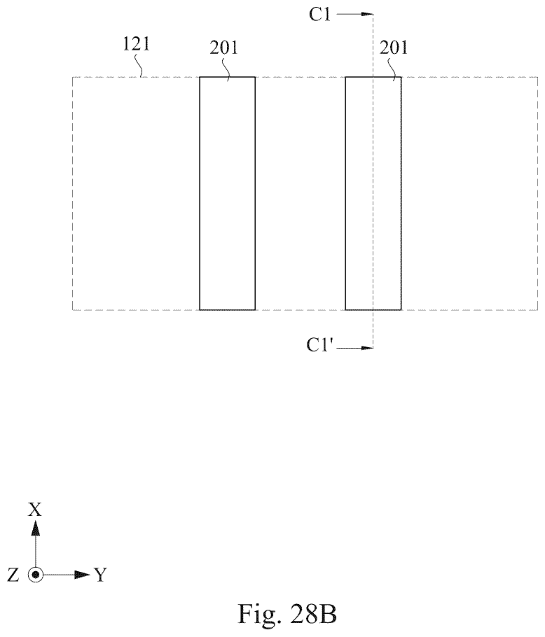

Reference is made to FIGS. 28A and 28B. An epitaxial stack is formed over the MEOL layer 121. The epitaxial stack includes sacrificial layers 201 of a first composition interposed by a channel layer 202 of a second composition. The first and second compositions can be different. In some embodiments, the sacrificial layers 201 may be made of SiGe and have a different germanium atomic concentrations than the channel layer 202. In some embodiments, the channel layer 201 may be made of silicon (Si). In some embodiments, the sacrificial layer 201 has a greater germanium atomic concentration than the channel layer 202. By way of example but not limitation, the sacrificial layer 201 may have a germanium atomic concentration in a range from about 10 to 90%, such as about 10, 20, 30, 40, 50, 60, 70, 80, 90%. However, other embodiments are possible including those that provide for the first and second compositions having different etch selectivity.

The use of the channel layer 202 to define a channel or channels of a device is further discussed below. It is noted that one layer of the channel layer 202 is arranged as illustrated in FIG. 28A, which is for illustrative purposes only and not intended to be limiting beyond what is specifically recited in the claims. It can be appreciated that any number of sacrificial layers can be formed in the epitaxial stack; the number of layers depending on the desired number of channels regions for the transistor. In some embodiments, the number of the channel layer 202 can be between about 1 and 100, such as 1, 10, 15, 20, 25, 30, 35, 40, 45, 50, 55, 60, 65, 70, 75, 80, 85, 90, 95, 100, or 101. As described in more detail below, the channel layer 202 may serve as a channel region for a subsequently-formed semiconductor device and the thickness is chosen based on device performance considerations. By way of example and not limitation, the thickness of the channel layer 202 can be in a range from about 0.5 to 50 nm, such as about 0.5, 1, 5, 10, 15, 20, 25, 30, 35, 40, 45, or 50 nm. In some embodiments, the length of the channel layer 202 can be in a range from 5 to 500 nm, such as about 5, 50, 100, 150, 200, 250, 300, 350, 400, 450, or 500 nm. In some embodiments, the channel layer 202 can have square/rectangle/diamond cross-sectional profile taken along the lengthwise direction of the gate structure. The sacrificial layer 201 in the channel region may eventually be removed and serve to define a vertical distance between adjacent channel region(s) for a subsequently-formed multi-gate device and the thickness is chosen based on device performance considerations. In some embodiment, the thickness of the sacrificial layer 201 can be in a range from about 5 to 100 nm, such as about 5, 10, 20, 30, 40, 50, 60, 70, 80, 90, or 100 nm.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the sacrificial layers 201 and channel layer 202 can include different materials than the substrate 100. As stated above, in at least some examples, the sacrificial layers 201 can include epitaxially grown silicon germanium (SiGe) layers, and the channel layer 202 can include an epitaxially grown silicon (Si) layer. Alternatively, in some embodiments, either of the sacrificial layers 201 and the channel layer 202 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the sacrificial layers 201 and the channel layer 202 may be chosen based on providing differing oxidation and/or etching selectivity properties.

Subsequently, the epitaxial stack includes the channel layer 202 and the sacrificial layers 201 can be patterned, such that the channel layer 202 and the sacrificial layers 201 or portions thereof may be formed nanostructures as shown in FIG. 28B. Specifically, the channel layer 102 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layers 202 and the sacrificial layers 201 may be fabricated using suitable processes including double-patterning or multi-patterning processes.

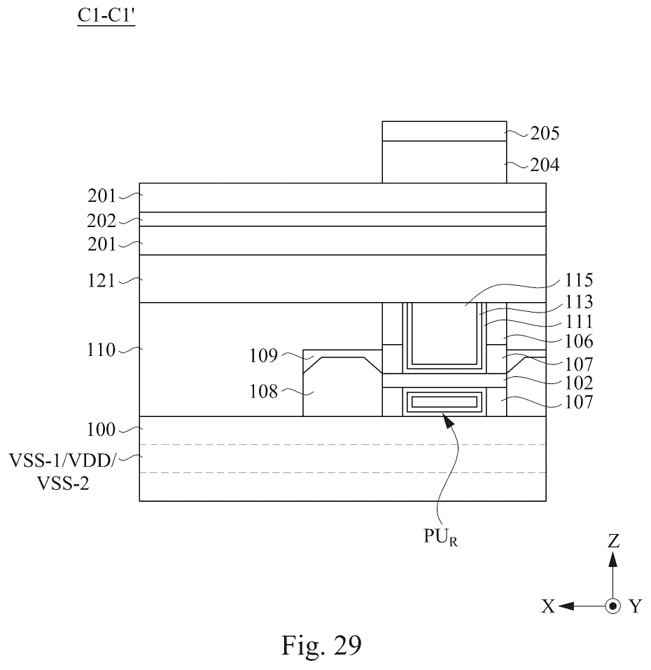

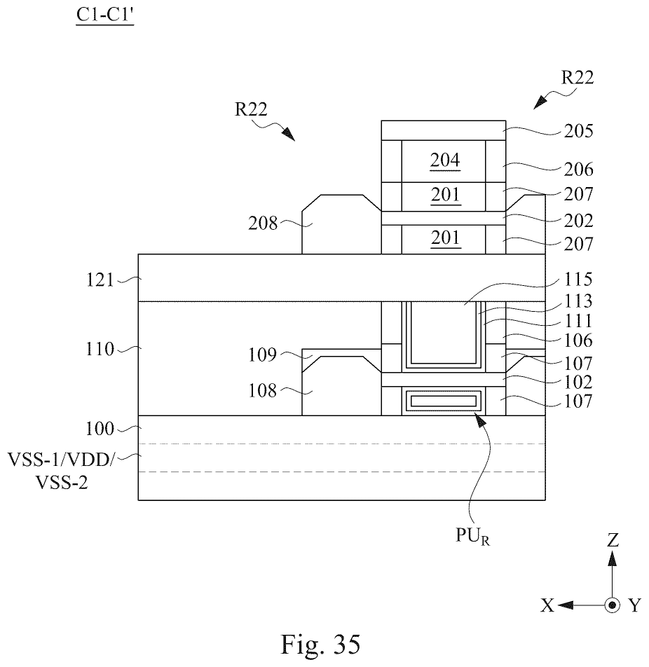

Reference is made to FIG. 29. Dummy gate layers 204 and hard mask layers 205 are formed over the epitaxial stack. Portions of the channel layer 202 underlying the dummy gate layers 204 may be referred to as the channel regions. The dummy gate layer 204 may also define source/drain regions 208 (see FIG. 35). Dummy gate formation operation forms the dummy gate layer 204 and the hard mask layer 205 over the dummy gate layer 204. The hard mask layer 205 is then patterned, followed by patterning the dummy gate layer 204 by using the patterned hard mask layer 205 as an etch mask. The etch process may include a wet etch, a dry etch, and/or combinations thereof.

In some embodiments, the dummy gate layer 204 may include polycrystalline-silicon (poly-Si), poly-crystalline silicon-germanium (poly-SiGe), metallic nitrides, metallic silicides, metallic oxides, or metals. In some embodiments, the dummy gate layer 204 may include a metal-containing material such as TiN, TaN, TaC, Co, Ru, Al, combinations thereof, or multi-layers thereof. The hard mask layer 205 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 204 may be deposited by CVD, physical vapor deposition (PVD), sputter deposition, or other techniques suitable for depositing conductive materials. In some embodiments, the hard mask layer 205 may be deposited by CVD, physical vapor deposition (PVD), sputter deposition, or other techniques suitable for depositing conductive materials. In some embodiments, the dummy gate layer 204 can be interchangeably referred to a dummy gate, a dummy gate pattern, a dummy gate strip, an isolation structure, or a dielectric gate.

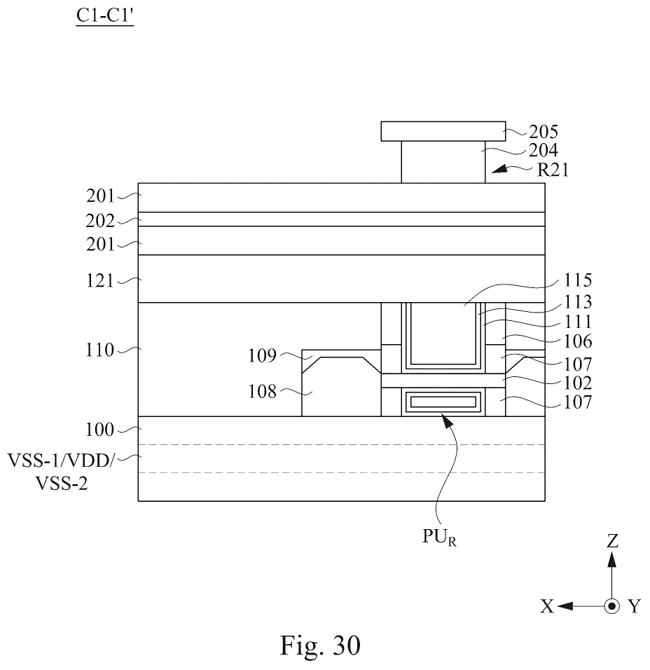

Reference is made to FIG. 30. The dummy gate layer 204 is laterally or horizontally recessed by using suitable etch techniques, resulting in lateral recesses R21 vertically between the sacrificial layer 201 and the hard mask layer 205. This operation may be performed by using a selective etching process. By way of example and not limitation, the sacrificial layer 201 may be made of SiGe, the hard mask layer 205 may be made of a dielectric material, and the dummy gate layer 204 may be made of silicon allowing for the selective etching of the dummy gate layer 204. In some embodiments, the selective dry etching etches Si at a faster etch rate than it etches SiGe and the dielectric material. As a result, the sacrificial layer 201 and the hard mask layer 205 laterally extend past opposite end surfaces of the dummy gate layer 204.

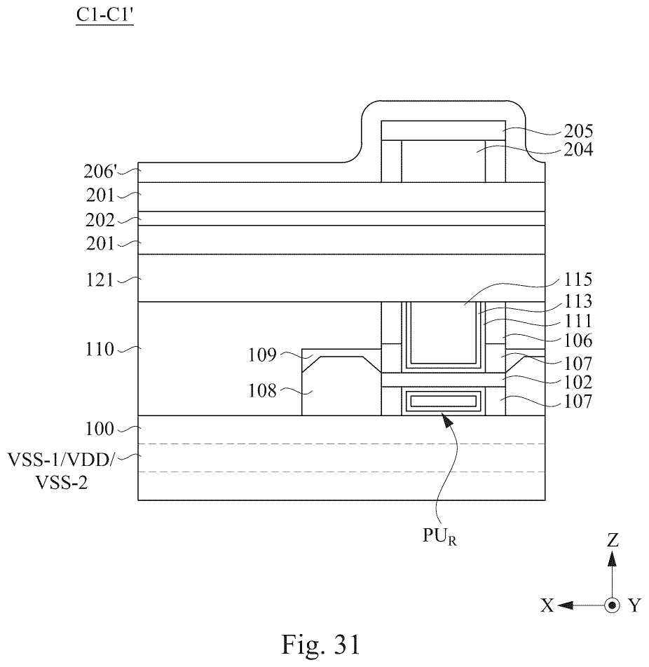

Reference is made to FIG. 31. After recession of the dummy gate layer 204 is completed, a spacer material 206′ is deposited over the MEOL layer 121. The spacer material 206′ may be a conformal layer on the topmost sacrificial layer 201, the dummy gate layers 204, and the hard mask layers 205. The spacer material 206′ may include a dielectric material such as silicon oxide, silicon nitride, silicon carbide, silicon oxynitride, SiCN films, silicon oxycarbide, SiOCN films, and/or combinations thereof. In some embodiments, the spacer material 206′ includes multiple layers, such as a first spacer layer and a second spacer layer formed over the first spacer layer. By way of example, the spacer material 206′ may be formed by depositing a dielectric material over the topmost sacrificial layer 201, the dummy gate layers 204, and the hard mask layers 205 using suitable deposition processes.

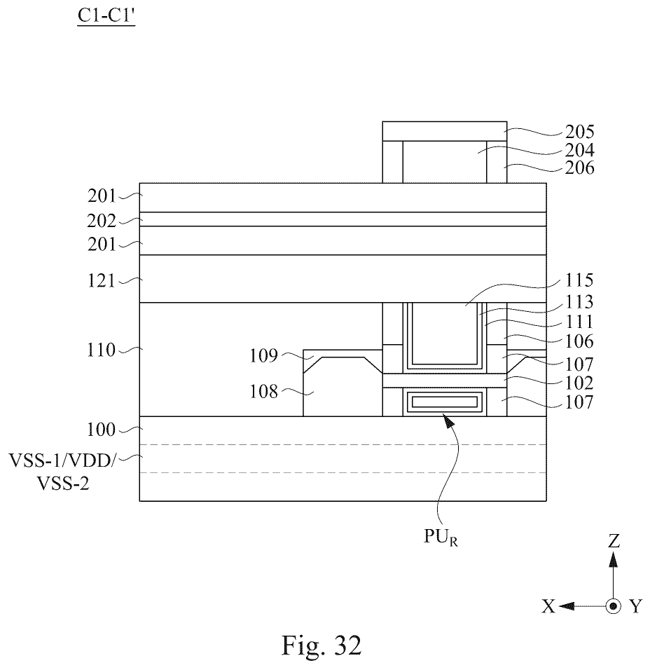

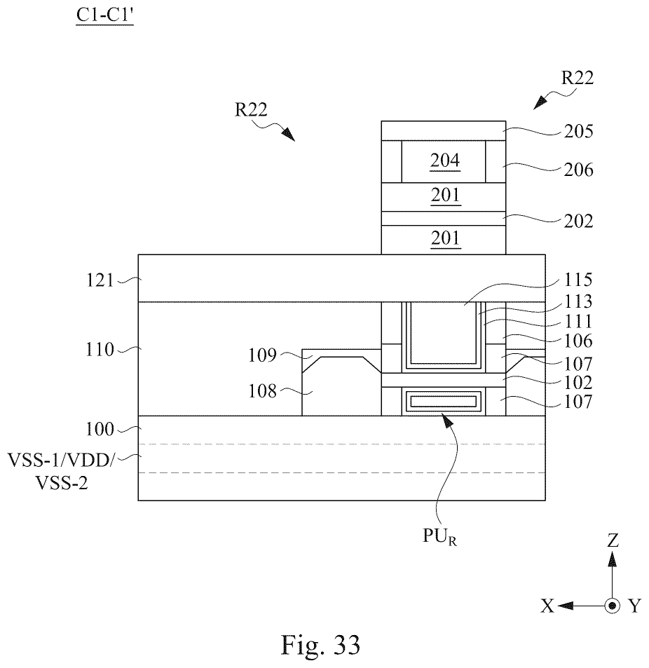

Reference is made to FIG. 32. An anisotropic etching process is then performed on the deposited spacer material 206′ to expose the topmost sacrificial layer 201 and the hard mask layers 205. Portions of the spacer material 206′ directly on the hard mask layers 205 and on the topmost sacrificial layer 201 not covered by the hard mask layers 205 may be completely removed by this anisotropic etching process. Portions of the spacer material 206′ on sidewalls of the recessed dummy gate layer 204 may remain in the lateral recesses R21, forming gate sidewall spacers 206, which are denoted as the gate spacers 206. In some embodiments, a lateral dimension (or thickness) of the sidewall spacer 206 can be in a range from about 1 to 25 nm, such as about 1, 2, 4, 6, 8, 10, 12, 14, 16, 18, 20, 22, 24, or 25 nm.

Reference is made to FIG. 33. Exposed portions of the patterned channel layer 202 and the patterned sacrificial layers 201 that extend laterally beyond the gate spacers 206 are etched by using, for example, an anisotropic etching process that uses the dummy gate layer 204 and the gate spacers 206 as an etch mask, resulting in recesses R22 into the channel layer 202 and the sacrificial layers 201. After the anisotropic etching, end surfaces of the patterned channel layer 202 and the patterned sacrificial layers 201 and respective outermost sidewalls of the gate spacers 206 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

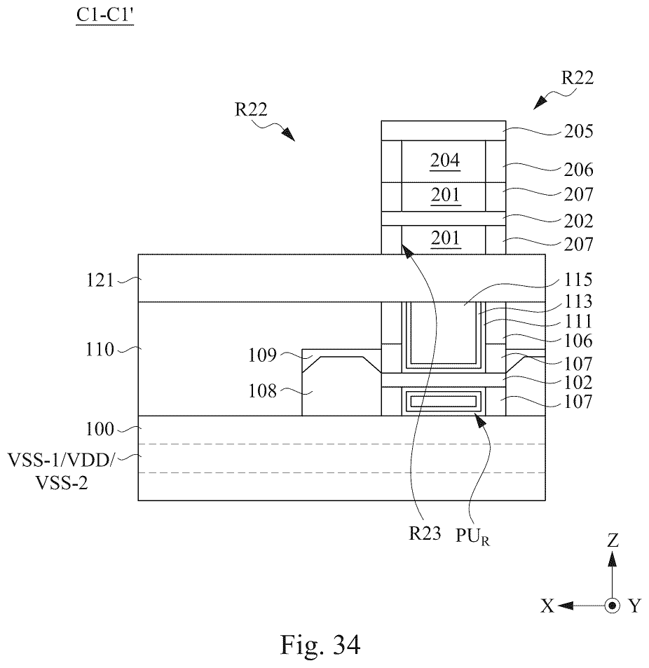

Reference is made to FIG. 34. The patterned sacrificial layers 201 are laterally or horizontally recessed by using suitable etch techniques, resulting in lateral recesses R23. This operation may be performed by using a selective etching process. By way of example and not limitation, the sacrificial layers 201 can be made of SiGe and the channel layer 202 can be made of silicon allowing for the selective etching of the sacrificial layers 201. In some embodiments, the selective dry etching etches SiGe at a faster etch rate than it etches Si. As a result, the patterned channel layer 202 laterally extends past opposite end surfaces of the patterned sacrificial layers 201.

Subsequently, inner spacers 207 are filled in the recesses R23, respectively. For example, spacer material layers are formed to fill the recesses R23 left by the lateral etching of the sacrificial layers 201 discussed above. The spacer material layer may be a low-k dielectric material, such as SiO₂, SiN, SiC, SION, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R23 left by the lateral etching of the sacrificial layers 201 are left. After the trimming process, the remaining portions of the deposited spacer material are denoted as inner spacers 207 in the recesses R23. The inner spacers 207 serve to isolate metal gates from source/drain regions formed in subsequent processing.

Reference is made to FIG. 35. Source/drain regions 208 are formed in the recesses R22 and connected to the channel layers 202. The source/drain regions 208 may be formed by performing an epitaxial growth process that provides an epitaxial material on the MEOL layer 121. During the epitaxial growth process, the dummy gate layer 204, the gate spacers 206, and the inner spacers 207 limit the source/drain regions 208 to the MEOL layer 121 and the channel layer 202. In some embodiments, the lattice constants of the source/drain regions 208 are different from the lattice constant of the channel layers 202, so that the channel layers 202 can be strained or stressed by the source/drain regions 208 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 202.

In some embodiments, the source/drain regions 208 may include Ge, Si, GaAs, AlGaAs, SiGe, GaAsP, SiP, or other suitable material. The source/drain regions 208 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 208 are not in-situ doped, an implantation process (i.e., a junction implant process) is performed to dope the source/drain regions 208. In some embodiments, the source/drain regions 208 can be in an n-type transistor and include SiP.

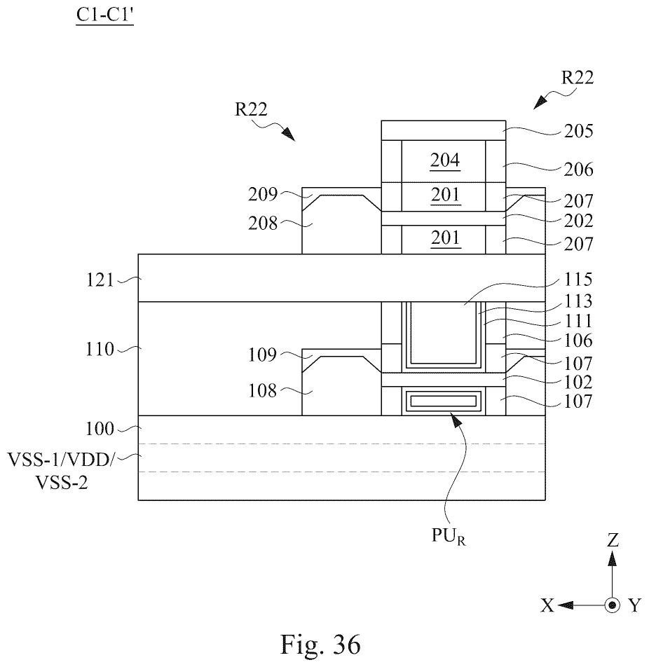

Reference is made to FIG. 36. Source/drain contacts 209 can be formed over the source/drain regions 208. In some embodiments, the source/drain contacts 209 may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, other suitable materials, or combinations thereof. In some embodiments, the formation of the source/drain contacts 209 can be performed by such as a lift-off process. By way of example and not limitation, a mask layer (not shown) can be formed by depositing a photoresist layer over the MEOL layer 121 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 209. Subsequently, a contact material can be deposited over the MEOL layer 121 and formed on the source/drain contacts 209 and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 208 are remained to form the source/drain contacts 209.

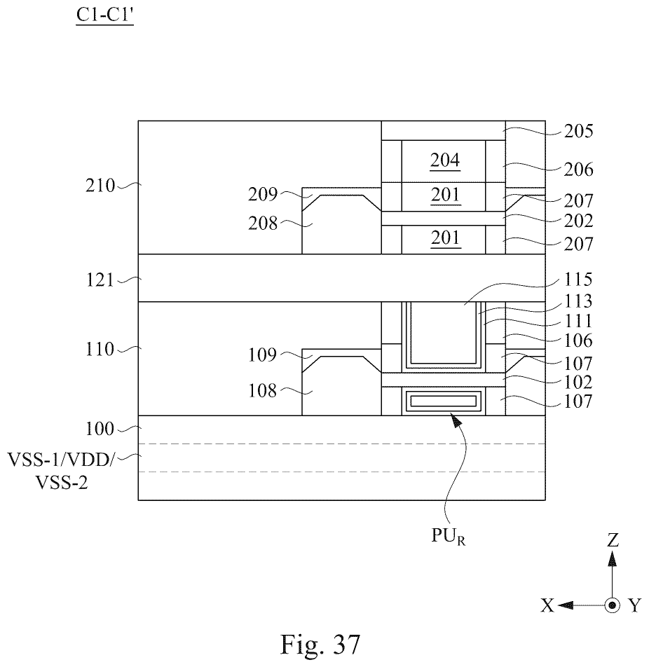

Reference is made to FIG. 37. An ILD layer 210 is formed over the MEOL layer 121. In some embodiments, the ILD layer 210 includes materials such as tetraethylorthosilicate (TEOS)-formed oxide, un-doped silicate glass, or doped silicon oxide such as borophosphosilicate glass (BPSG), fused silica glass (FSG), dielectric materials. In some embodiments, the ILD layer 210 may be deposited by a plasma-enhanced chemical vapor deposition (PECVD) process or other suitable deposition technique. In some embodiments, after formation of the ILD layer 210, the substrate 100 may be subject to a high thermal budget process to anneal the ILD layer 210. Subsequently, a planarization process (e.g., CMP) is performed to remove the excessive ILD layer 210 above the hard mask layer 205 until the hard mask layer 205 is exposed. In some embodiments, the hard mask layer 205 may also act as an etch stop layer for etching the ILD layer 210.

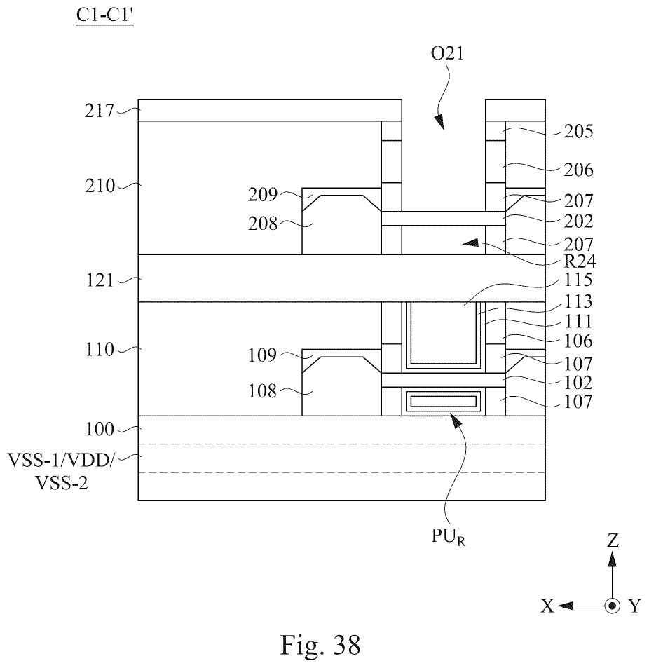

Reference is made to FIG. 38. A hard mask layer 217 may be formed over the ILD layer 210 and the hard mask layer 205. In some embodiments, the hard mask layer 217 may be made of the same material as the ILD layer 210, thereby resulting in a substantially indistinguishable interface between the hard mask layer 217 and the ILD layer 210. In some embodiments, the hard mask layer 217 may be made of a different material than the ILD layer 210. In some embodiments, the hard mask layer 217 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 217 can be performed by using any suitable method, such as CVD, physical vapor deposition (PVD), ALD, PEALD, PECVD, SACVD, FCVD, spin-on, and/or the like, or a combination thereof. Subsequently, the hard mask layer 217 may be patterned and then be used to etch the dummy gate layer 204 (see FIG. 37), the hard mask layer 205, and the ILD layer 210. The hard mask layer 217 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 217, the dummy gate layer 204 (see FIG. 37), the hard mask layer 205, and the ILD layer 210 can be etched through the patterned hard mask layer 217 to form an opening O21. The opening O21 can expose a sidewall of the epitaxial stack, such that the channel layer 202 and the sacrificial layers 201 can be exposed from the opening O21. The etching process may include dry etching, wet etching, and/or other etching methods (e.g., reactive ion etching). In some embodiments, the opening O21 may have a rectangular profile extending along Y-direction from the top view. After the formation of the opening O21, the patterned mask can be removed by a suitable technique, such as a wet clean process, an ashing process, or the like.

Subsequently, the sacrificial layers 201 are removed in one or more etching process, so that a recess R24 can be formed to inherit the shape of a lower one of the sacrificial layers 201. The recess R24 can expose a bottom surface of the channel layer 202, and the opening O21 can expose a top surface of the channel layer 202. In some embodiments, the sacrificial layers 201 can be removed by an anisotropic dry etch process. For example, the etching process may include a dry etch process using reaction gas(es) that selectively etch the sacrificial layers 201 at faster rates than channel layer 202.

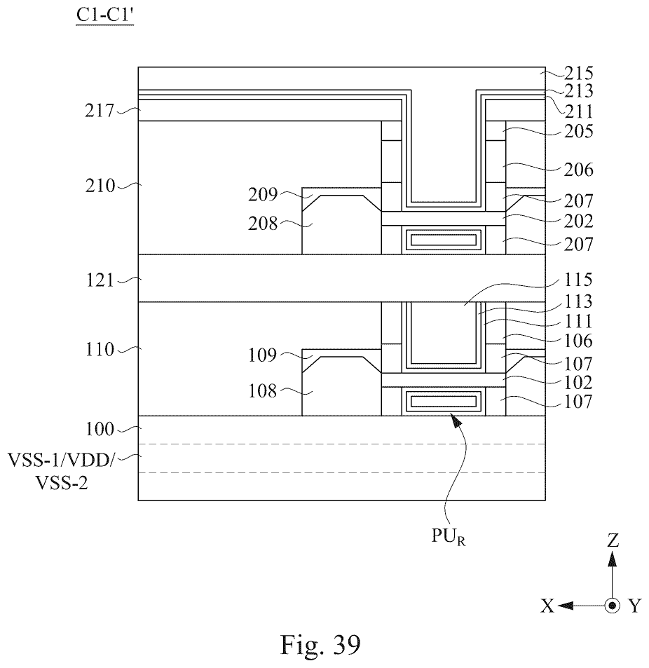

Reference is made to FIG. 39. An interfacial layer 211 and a high-k dielectric layer 213 can be conformally formed over the hard mask layer 217 and in the opening O21 and the recesses R24. In some embodiments, the interfacial layer 211 may include a dielectric material such as silicon oxide (SiO₂), HfSiO, or silicon oxynitride (SiON). In some embodiments, the interfacial layer 211 may be deposited using any suitable method, such as CVD, physical vapor deposition (PVD), ALD, PEALD, PECVD, SACVD, FCVD, spin-on, and/or the like, or a combination thereof. In some embodiments, the high-k dielectric layer 213 may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 213 may be deposited using any suitable method, such as CVD, physical vapor deposition (PVD), ALD, PEALD, PECVD, SACVD, FCVD, spin-on, and/or the like, or a combination thereof.

Subsequently, a gate electrode layer 215 can be deposited over the high-k dielectric layer 213. The gate electrode layer 215 may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, or other suitable materials.

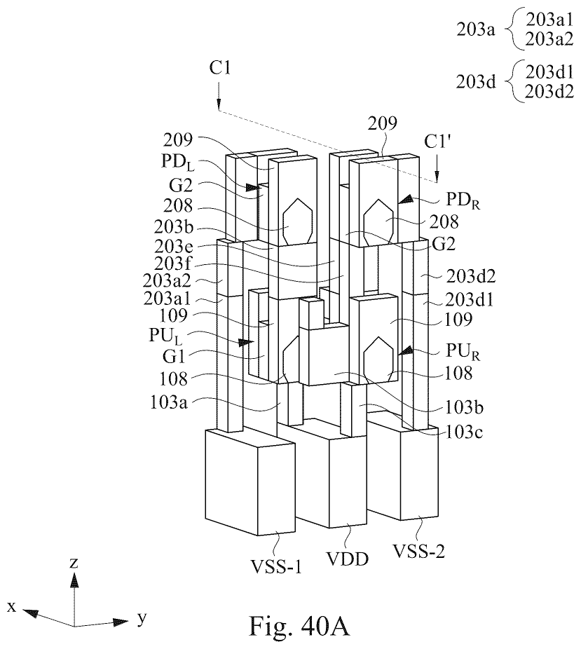

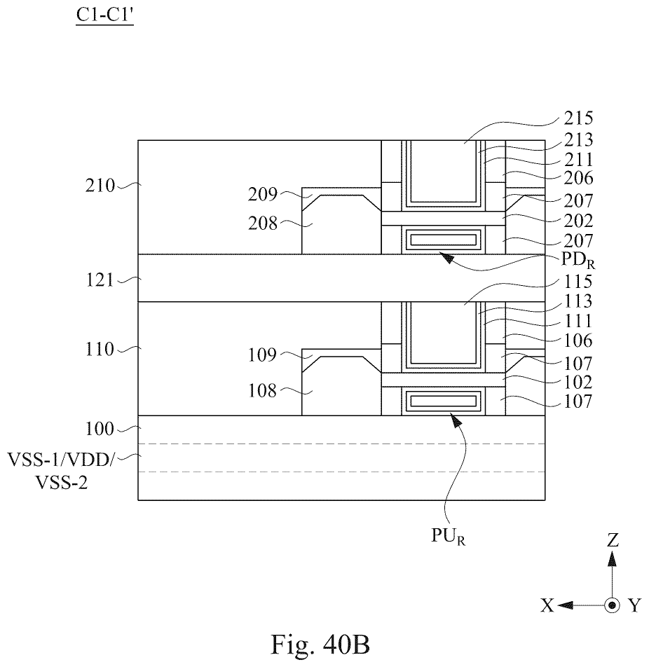

Reference is made to FIGS. 40A and 40B. A planarization process (e.g., CMP) is performed to remove the excessive gate electrode layer 215, the high-k dielectric layer 213, the interfacial layer 211, and the hard mask layers 205 and 217 above the gate spacers 206. The gate spacers 106 may also act as an etch stop layer for etching the gate electrode layer 215, the high-k dielectric layer 213, the interfacial layer 211, and the hard mask layers 205 and 217. Therefore, a (metal) gate structure G2 including the gate electrode layer 215, the high-k dielectric layer 213, and the interfacial layer 211 can be formed in the recesses R24 to surround the channel layer 202 suspended in the recesses R24. In some embodiments, the gate structure G2 may be the final gate of a GAA FET. Therefore, the semiconductor structure can include the transistors PD_{R} and PD_{L}. The transistor PD_{R} is over the transistor PU_{R}, and the transistor PD_{L} is over the transistor PU_{L}. The transistors PD_{R} and PD_{L} each can include the channel layer 202, the gate structure G2 wrapping around the channel layer 202, and the source/drain regions 208 on opposite sides of the gate structure G2 and connected to the channel layer 202. In some embodiments, the transistors PD_{R} and PD_{L} can be interchangeably referred to as middle-tier transistors.

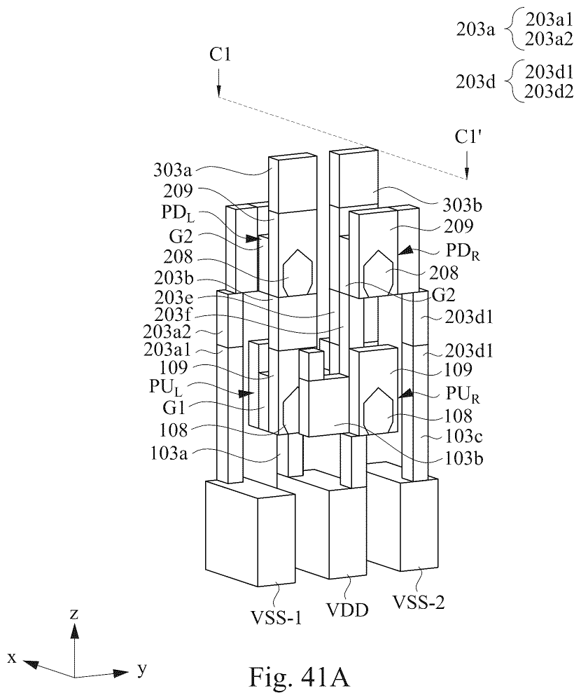

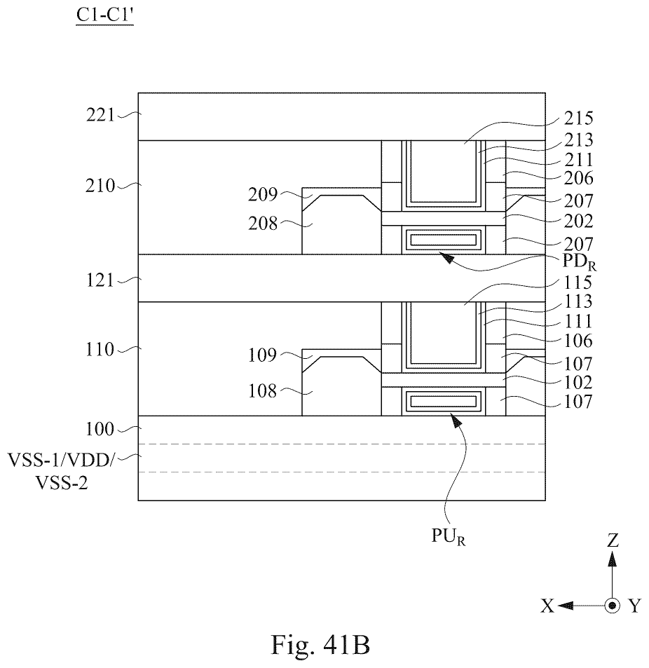

Reference is made to FIGS. 41A and 41B. A MEOL layer 221 can be formed over the transistors PD_{R} and PD_{L}. The MEOL layer 221 may include an inter-metal dielectric and conductive interconnect to connect the transistors PD_{R} and PD_{L} to the overlying features (e.g., transistors PG_{R1}, PG_{L1}, PG_{R2}, PG_{L2}). In some embodiments, the inter-metal dielectric may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the conductive interconnect formed in the inter-metal dielectric can include the contacts 303a and 303b. The contact 303a can be formed on the second one of the source/drain regions 208 of the transistor PD_{L}, connecting a sharing overlying source/drain region 308 of the transistors PG_{L. 2} and PG_{L2} (see FIG. 3A). The contact 303b can be formed on the second one of the source/drain regions 208 of the transistor PD_{R}, connecting a sharing overlying source/drain region 308 of the transistors PG _{R. 2} and PG_{R2} (see FIG. 3A). In some embodiments, the conductive interconnect can be made of tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, or other suitable materials.

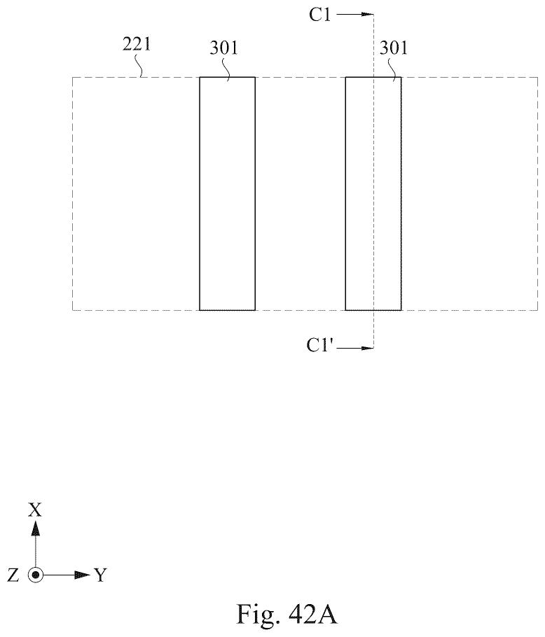

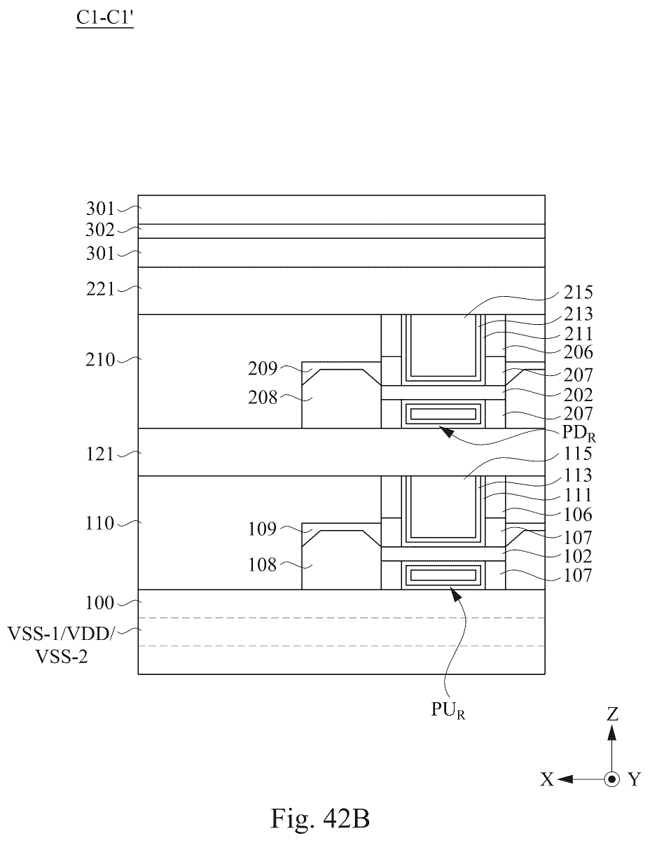

Reference is made to FIGS. 42A and 42B. An epitaxial stack is formed over the MEOL layer 221. The epitaxial stack includes sacrificial layers 301 of a first composition interposed by a channel layer 302 of a second composition. The first and second compositions can be different. In some embodiments, the sacrificial layers 301 may be made of SiGe and have a different germanium atomic concentrations than the channel layer 302. In some embodiments, the channel layer 301 may be made of silicon (Si). In some embodiments, the sacrificial layer 301 has a greater germanium atomic concentration than the channel layer 302. By way of example but not limitation, the sacrificial layer 301 may have a germanium atomic concentration in a range from about 10 to 90%, such as about 10, 20, 30, 40, 50, 60, 70, 80, 90%. However, other embodiments are possible including those that provide for the first and second compositions having different etch selectivity.

The use of the channel layer 302 to define a channel or channels of a device is further discussed below. It is noted that one layer of the channel layer 302 is arranged as illustrated in FIG. 42B, which is for illustrative purposes only and not intended to be limiting beyond what is specifically recited in the claims. It can be appreciated that any number of sacrificial layers can be formed in the epitaxial stack; the number of layers depending on the desired number of channels regions for the transistor. In some embodiments, the number of the channel layer 302 can be between about 1 and 100, such as 1, 10, 15, 20, 25, 30, 35, 40, 45, 50, 55, 60, 65, 70, 75, 80, 85, 90, 95, 100, or 101. As described in more detail below, the channel layer 302 may serve as a channel region for a subsequently-formed semiconductor device and the thickness is chosen based on device performance considerations. By way of example and not limitation, the thickness of the channel layer 302 can be in a range from about 0.5 to 50 nm, such as about 0.5, 1, 5, 10, 15, 20, 25, 30, 35, 40, 45, or 50 nm. In some embodiments, the length of the channel layer 302 can be in a range from 5 to 500 nm, such as about 5, 50, 100, 150, 200, 250, 300, 350, 400, 450, or 500 nm. In some embodiments, the channel layer 302 can have square/rectangle/diamond cross-sectional profile taken along the lengthwise direction of the gate structure. The sacrificial layer 301 in the channel region may eventually be removed and serve to define a vertical distance between adjacent channel region(s) for a subsequently-formed multi-gate device and the thickness is chosen based on device performance considerations. In some embodiment, the thickness of the sacrificial layer 301 can be in a range from about 5 to 100 nm, such as about 5, 10, 20, 30, 40, 50, 60, 70, 80, 90, or 100 nm.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the sacrificial layers 301 and channel layer 302 can include different materials than the substrate 100. As stated above, in at least some examples, the sacrificial layers 301 can include epitaxially grown silicon germanium (SiGe) layers, and the channel layer 302 can include an epitaxially grown silicon (Si) layer. Alternatively, in some embodiments, either of the sacrificial layers 301 and the channel layer 302 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the sacrificial layers 301 and the channel layer 302 may be chosen based on providing differing oxidation and/or etching selectivity properties.

Subsequently, the epitaxial stack includes the channel layer 302 and the sacrificial layers 301 can be patterned, such that the channel layer 302 and the sacrificial layers 301 or portions thereof may be formed nanostructures as shown in FIG. 42B. Specifically, the channel layer 302 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layers 302 and the sacrificial layers 301 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer can be formed over the MEOL layer 221 and patterned using a photolithography process. Spacers are formed alongside the patterned sacrificial layer using a self-aligned process. The sacrificial layer is then removed. The etching process can include dry etching, wet etching, reactive ion etching (RIE), and/or other suitable processes.

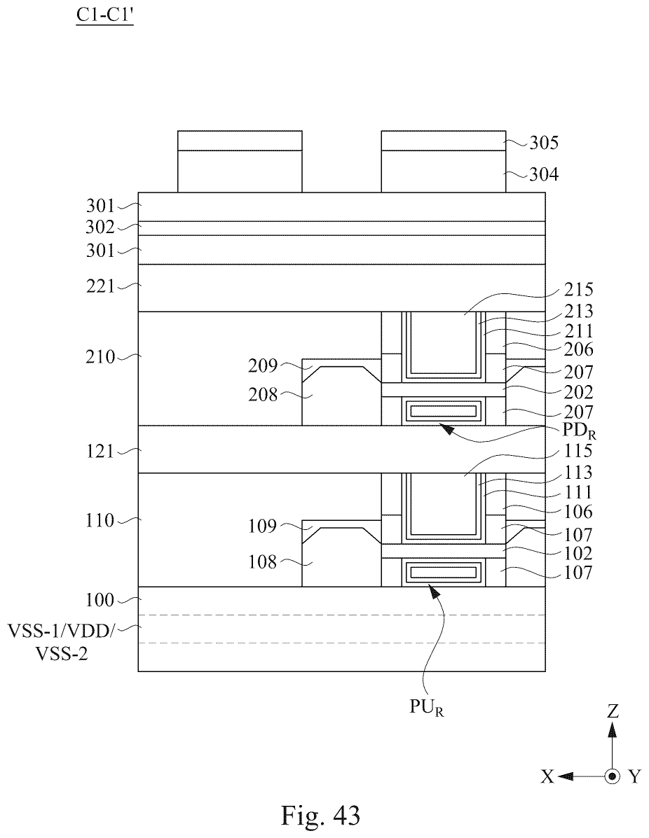

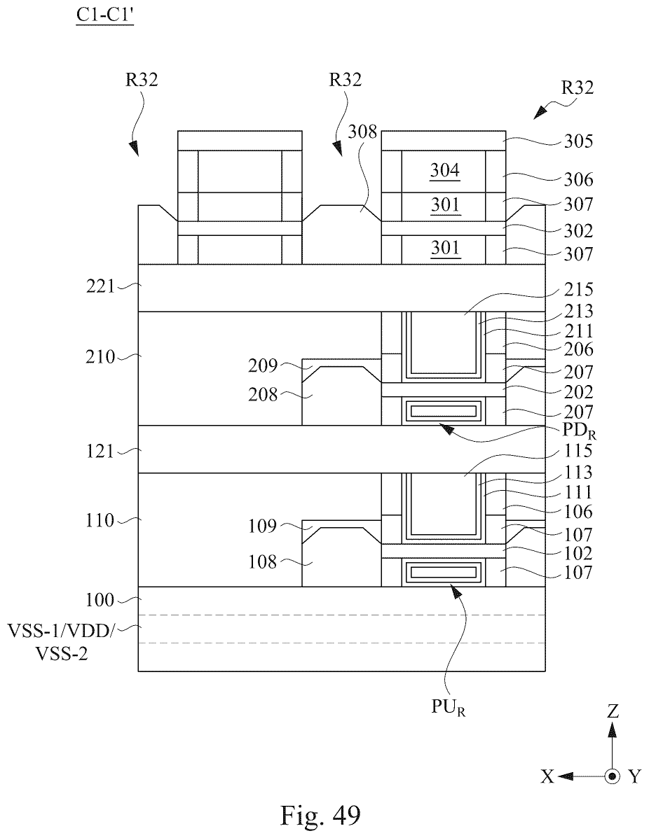

Reference is made to FIG. 43. Dummy gate layers 304 and hard mask layers 305 are formed over the epitaxial stack. Portions of the channel layer 302 underlying the Dummy gate layers 304 may be referred to as the channel regions. The dummy gate layer 304 may also define source/drain regions 308 (see FIG. 49). Dummy gate formation operation forms the dummy gate layer 304 and the hard mask layer 305 over the dummy gate layer 304. The hard mask layer 305 is then patterned, followed by patterning the dummy gate layer 304 by using the patterned hard mask layer 305 as an etch mask. The etch process may include a wet etch, a dry etch, and/or combinations thereof.

In some embodiments, the dummy gate layer 304 may include polycrystalline-silicon (poly-Si), poly-crystalline silicon-germanium (poly-SiGe), metallic nitrides, metallic silicides, metallic oxides, or metals. In some embodiments, the dummy gate layer 304 may include a metal-containing material such as TiN, TaN, TaC, Co, Ru, Al, combinations thereof, or multi-layers thereof. The hard mask layer 305 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 304 may be deposited by CVD, physical vapor deposition (PVD), sputter deposition, or other techniques suitable for depositing conductive materials. In some embodiments, the hard mask layer 305 may be deposited by CVD, physical vapor deposition (PVD), sputter deposition, or other techniques suitable for depositing conductive materials. In some embodiments, the dummy gate layer 305 can be interchangeably referred to a dummy gate, a dummy gate pattern, a dummy gate strip, an isolation structure, or a dielectric gate.

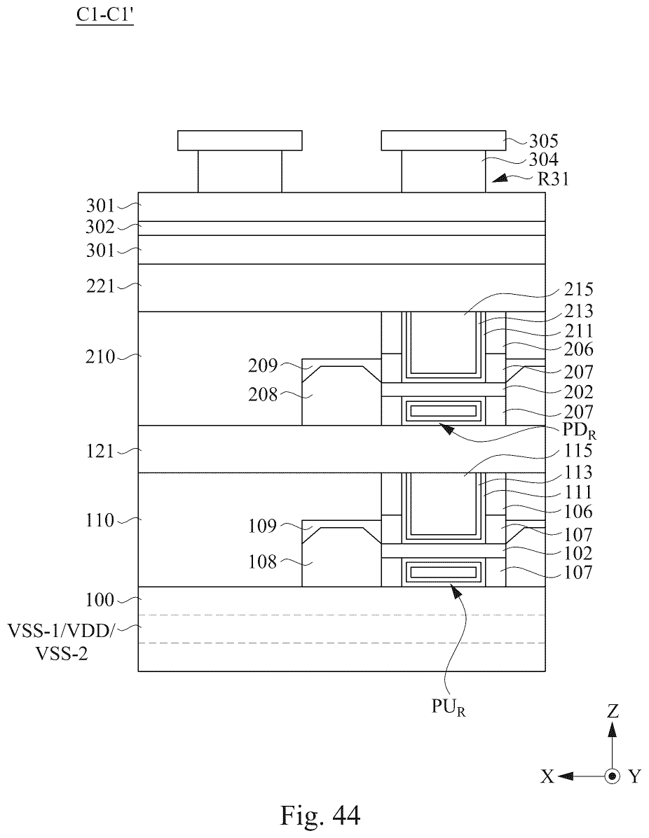

Reference is made to FIG. 44. The dummy gate layer 304 is laterally or horizontally recessed by using suitable etch techniques, resulting in lateral recesses R31 vertically between the sacrificial layer 301 and the hard mask layer 305. This operation may be performed by using a selective etching process. By way of example and not limitation, the sacrificial layer 301 may be made of SiGe, the hard mask layer 305 may be made of a dielectric material, and the dummy gate layer 304 may be made of silicon allowing for the selective etching of the dummy gate layer 304. In some embodiments, the selective dry etching etches Si at a faster etch rate than it etches SiGe and the dielectric material. As a result, the sacrificial layer 301 and the hard mask layer 305 laterally extend past opposite end surfaces of the dummy gate layer 304.

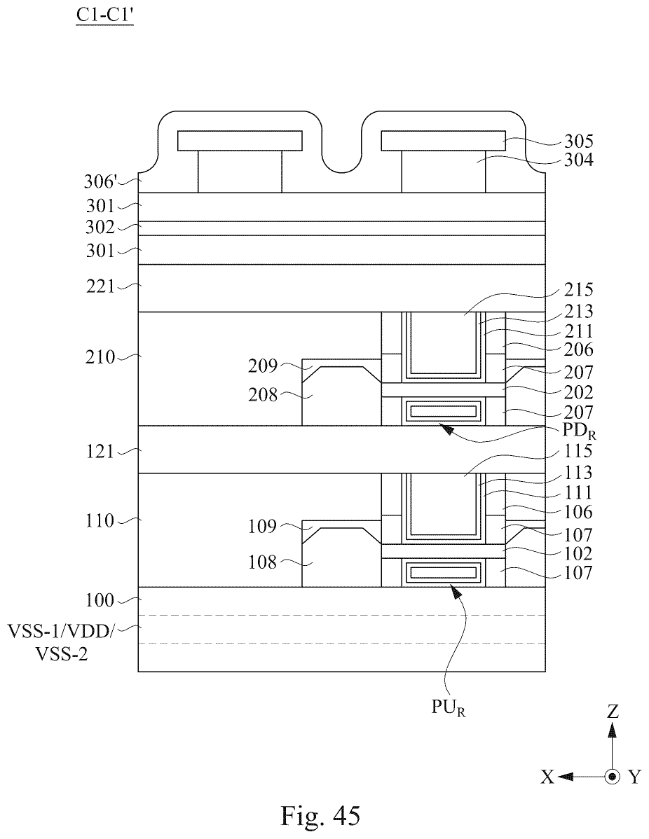

Reference is made to FIG. 45. After recession of the dummy gate layer 304 is completed, a spacer material 306′ is deposited over the MEOL layer 221. The spacer material 306′ may be a conformal layer on the topmost sacrificial layer 301, the Dummy gate layers 304, and the hard mask layers 305. The spacer material 306′ may include a dielectric material such as silicon oxide, silicon nitride, silicon carbide, silicon oxynitride, SiCN films, silicon oxycarbide, SiOCN films, and/or combinations thereof. In some embodiments, the spacer material 306′ includes multiple layers, such as a first spacer layer and a second spacer layer formed over the first spacer layer. By way of example, the spacer material 306′ may be formed by depositing a dielectric material over the topmost sacrificial layer 301, the Dummy gate layers 304, and the hard mask layers 305 using suitable deposition processes.

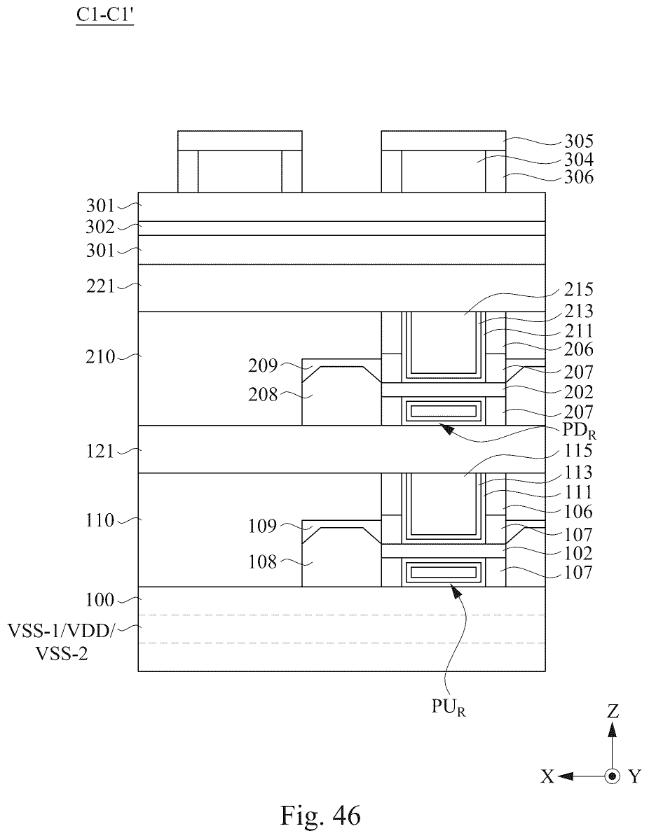

Reference is made to FIG. 46. An anisotropic etching process is then performed on the deposited spacer material 306′ to expose the topmost sacrificial layer 301 and the hard mask layers 305. Portions of the spacer material 306′ directly on the hard mask layers 305 and on the topmost sacrificial layer 301 not covered by the hard mask layers 305 may be completely removed by this anisotropic etching process. Portions of the spacer material 306′ on sidewalls of the recessed dummy gate layer 304 may remain in the lateral recesses R31, forming gate sidewall spacers 306, which are denoted as the gate spacers 306. In some embodiments, a lateral dimension (or thickness) of the sidewall spacer 306 can be in a range from about 1 to 25 nm, such as about 1, 2, 4, 6, 8, 10, 12, 14, 16, 18, 20, 22, 24, or 25 nm.

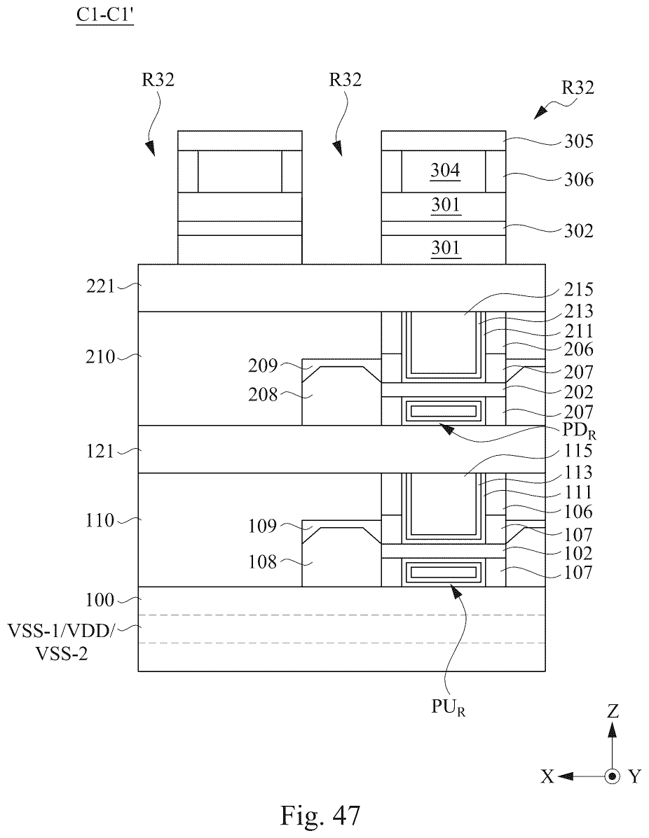

Reference is made to FIG. 47. Exposed portions of the patterned channel layer 302 and the patterned sacrificial layers 301 that extend laterally beyond the gate spacers 306 are etched by using, for example, an anisotropic etching process that uses the dummy gate layer 304 and the gate spacers 306 as an etch mask, resulting in recesses R32 into the channel layer 302 and the sacrificial layers 301. After the anisotropic etching, end surfaces of the patterned channel layer 302 and the patterned sacrificial layers 301 and respective outermost sidewalls of the gate spacers 306 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

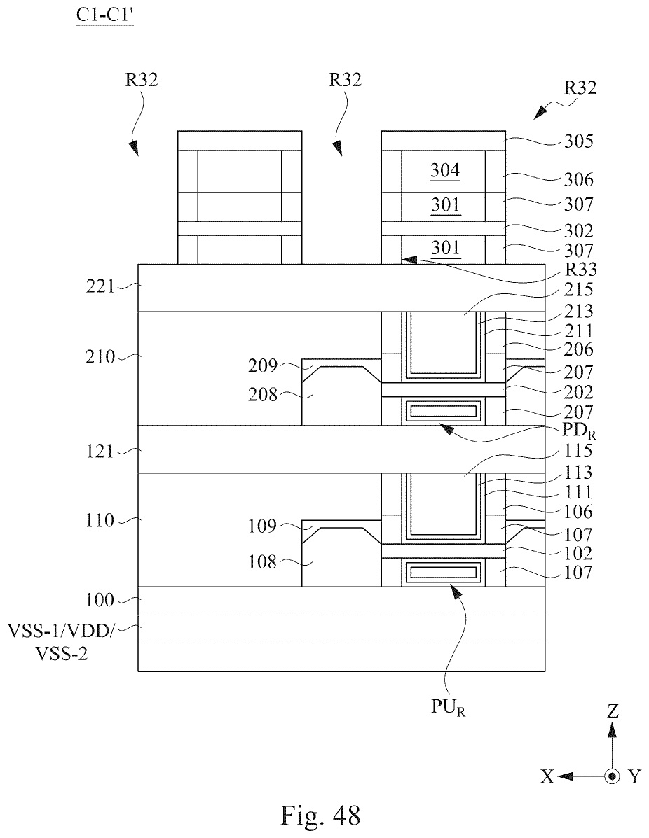

Reference is made to FIG. 48. The patterned sacrificial layers 301 are laterally or horizontally recessed by using suitable etch techniques, resulting in lateral recesses R33. This operation may be performed by using a selective etching process. By way of example and not limitation, the sacrificial layers 301 can be made of SiGe and the channel layer 302 can be made of silicon allowing for the selective etching of the sacrificial layers 301. In some embodiments, the selective dry etching etches SiGe at a faster etch rate than it etches Si. As a result, the patterned channel layer 302 laterally extends past opposite end surfaces of the patterned sacrificial layers 301.

Subsequently, inner spacers 307 are filled in the recesses R33, respectively. For example, spacer material layers are formed to fill the recesses R33 left by the lateral etching of the sacrificial layers 301 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R33 left by the lateral etching of the sacrificial layers 301 are left. After the trimming process, the remaining portions of the deposited spacer material are denoted as inner spacers 307 in the recesses R33. The inner spacers 307 serve to isolate metal gates from source/drain regions formed in subsequent processing.

Reference is made to FIG. 49. Source/drain regions 308 are formed in the recesses R32 and connected to the channel layers 302. The source/drain regions 308 may be formed by performing an epitaxial growth process that provides an epitaxial material on the MEOL layer 221. During the epitaxial growth process, the dummy gate layer 304, the gate spacers 306, and the inner spacers 307 limit the source/drain regions 308 to the MEOL layer 221 and the channel layer 302. In some embodiments, the lattice constants of the source/drain regions 308 are different from the lattice constant of the channel layers 302, so that the channel layers 302 can be strained or stressed by the source/drain regions 308 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 302.

In some embodiments, the source/drain regions 308 may include Ge, Si, GaAs, AlGaAs, SiGe, GaAsP, SiP, or other suitable material. The source/drain regions 308 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 308 are not in-situ doped, an implantation process (i.e., a junction implant process) is performed to dope the source/drain regions 308. In some embodiments, the source/drain regions 308 can be in an n-type transistor and include SiP.

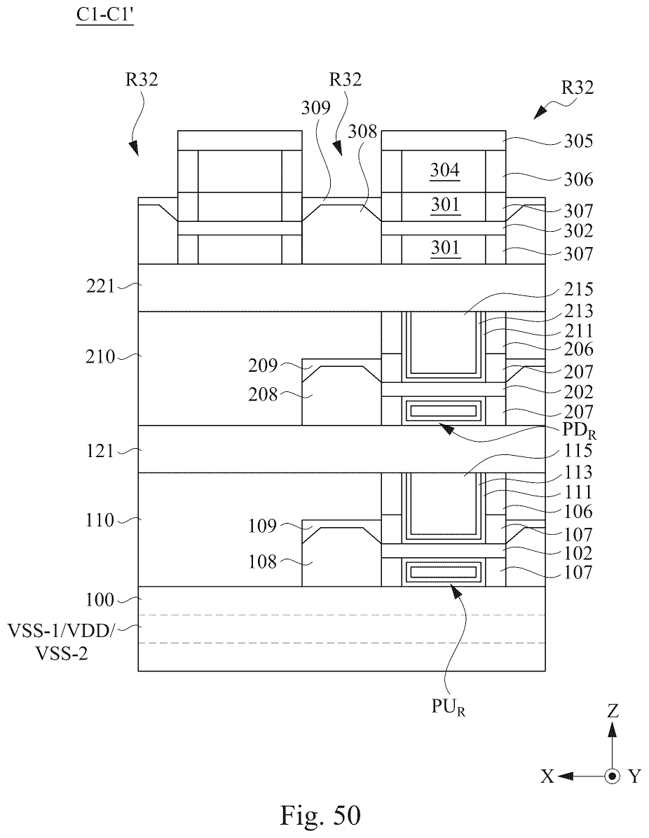

Reference is made to FIG. 50. Source/drain contacts 309 can be formed over the source/drain regions 308. In some embodiments, the Source/drain contacts 309 may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, other suitable materials, or combinations thereof. In some embodiments, the formation of the Source/drain contacts 309 can be performed by such as a lift-off process. By way of example and not limitation, a mask layer (not shown) can be formed by depositing a photoresist layer over the MEOL layer 221 by suitable process, such as spin-coating technique, which may include baking the photoresist layer after coating. In some embodiments, the mask layer may include a photoresist material including positive-type or negative-type resist materials. The mask layer can be patterned to form openings exposing the Source/drain contacts 309. Subsequently, a contact material can be deposited over the MEOL layer 221 and formed on the Source/drain contacts 309 and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 308 are remained to form the Source/drain contacts 309.

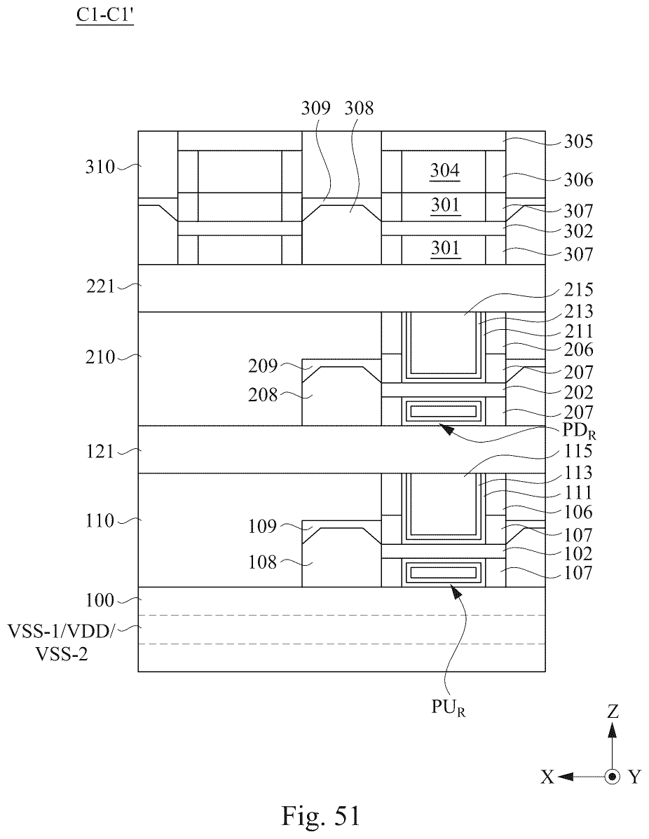

Reference is made to FIG. 51. An ILD layer 310 is formed over the MEOL layer 221. In some embodiments, the ILD layer 310 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 310 may be deposited by a plasma-enhanced chemical vapor deposition (PECVD) process or other suitable deposition technique. In some embodiments, after formation of the ILD layer 310, the substrate 100 may be subject to a high thermal budget process to anneal the ILD layer 310. Subsequently, a planarization process (e.g., CMP) is performed to remove the excessive ILD layer 310 above the hard mask layer 305 until the hard mask layer 305 is exposed. In some embodiments, the hard mask layer 305 may also act as an etch stop layer for etching the ILD layer 310.

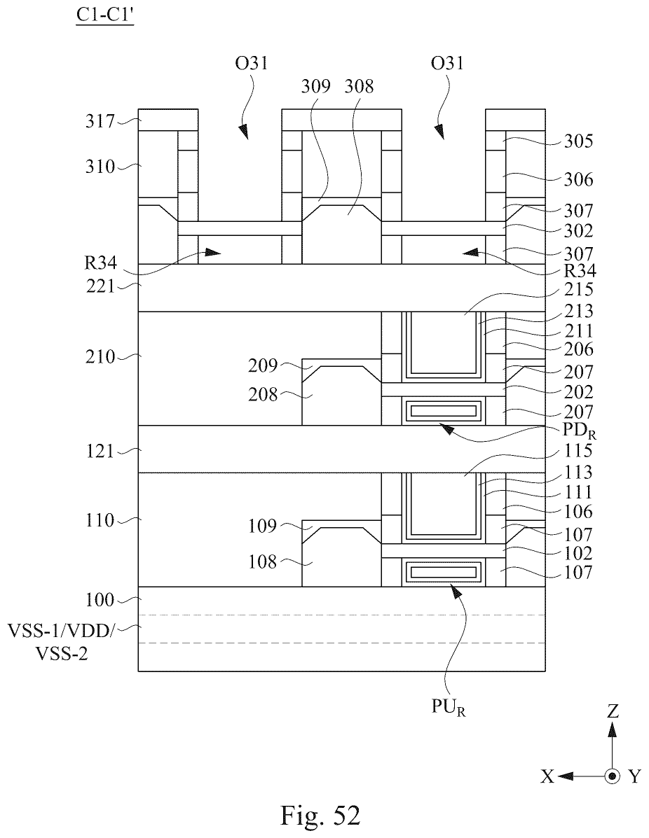

Reference is made to FIG. 52. A hard mask layer 317 may be formed over the ILD layer 310 and the hard mask layer 305. In some embodiments, the hard mask layer 317 may be made of the same material as the ILD layer 310, thereby resulting in a substantially indistinguishable interface between the hard mask layer 317 and the ILD layer 310. In some embodiments, the hard mask layer 317 may be made of a different material than the ILD layer 310. In some embodiments, the hard mask layer 317 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 317 can be performed by using any suitable method, such as CVD, physical vapor deposition (PVD), ALD, PEALD, PECVD, SACVD, FCVD, spin-on, and/or the like, or a combination thereof. Subsequently, the hard mask layer 317 may be patterned and then be used to etch the dummy gate layer 304 (see FIG. 51), the hard mask layer 305, and the ILD layer 310. The hard mask layer 317 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 317, the dummy gate layer 304 (see FIG. 51), the hard mask layer 305, and the ILD layer 310 can be etched through the patterned hard mask layer 317 to form an opening O31. The opening O31 can expose a sidewall of the epitaxial stack, such that the channel layer 302 and the sacrificial layers 301 can be exposed from the opening O31. The etching process may include dry etching, wet etching, and/or other etching methods (e.g., reactive ion etching). In some embodiments, the opening O31 may have a rectangular profile extending along Y-direction from the top view. After the formation of the opening O31, the patterned mask can be removed by a suitable technique, such as a wet clean process, an ashing process, or the like.

Subsequently, the sacrificial layers 301 are removed in one or more etching process, so that a recess R34 can be formed to inherit the shape of a lower one of the sacrificial layers 301. The recess R34 can expose a bottom surface of the channel layer 302, and the opening O31 can expose a top surface of the channel layer 302. In some embodiments, the sacrificial layers 301 can be removed by an anisotropic dry etch process. For example, the etching process may include a dry etch process using reaction gas(es) that selectively etch the sacrificial layers 301 at faster rates than channel layer 302.

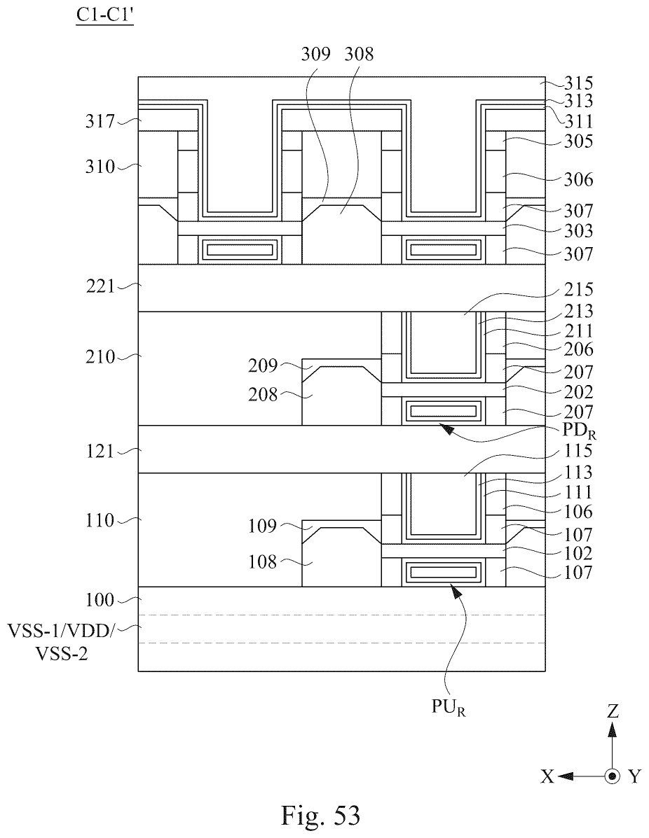

Reference is made to FIG. 53. An interfacial layer 311 and a high-k dielectric layer 313 can be conformally formed over the hard mask layer 317 and in the opening O31 and the recesses R34. In some embodiments, the interfacial layer 311 may include a dielectric material such as silicon oxide (SiO₂), HfSiO, or silicon oxynitride (SiON). In some embodiments, the interfacial layer 311 may be deposited using any suitable method, such as CVD, physical vapor deposition (PVD), ALD, PEALD, PECVD, SACVD, FCVD, spin-on, and/or the like, or a combination thereof. In some embodiments, the high-k dielectric layer 313 may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 313 may be deposited using any suitable method, such as CVD, physical vapor deposition (PVD), ALD, PEALD, PECVD, SACVD, FCVD, spin-on, and/or the like, or a combination thereof.

Subsequently, a gate electrode layer 315 can be deposited over the high-k dielectric layer 313. The gate electrode layer 315 may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, or other suitable materials.

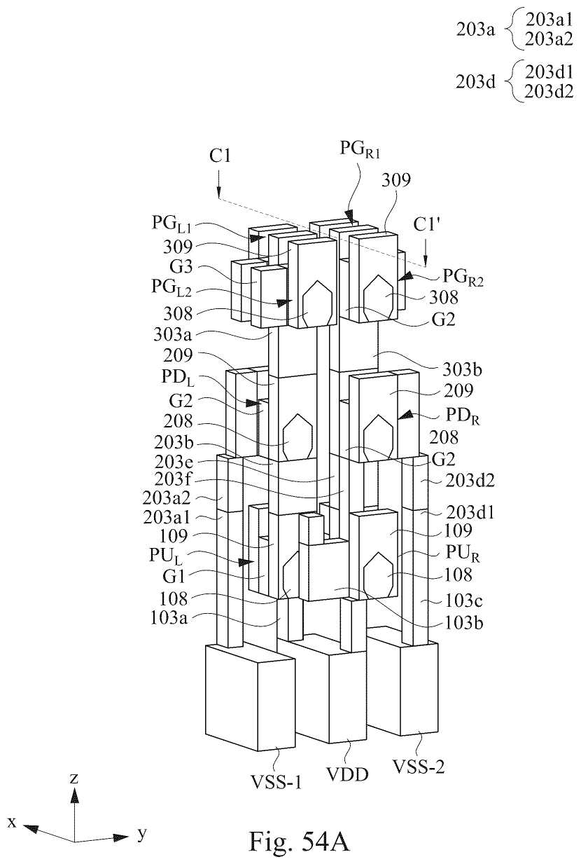

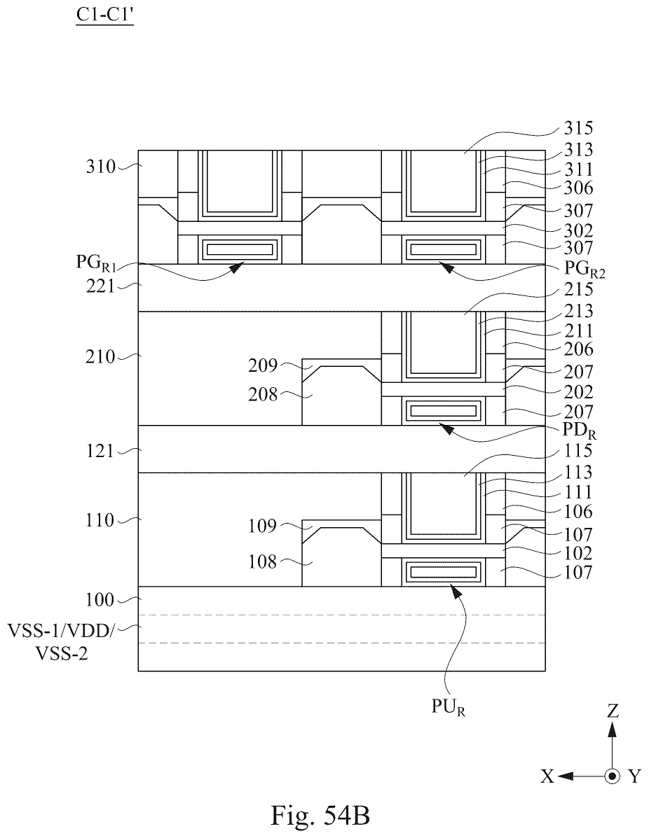

Reference is made to FIGS. 54A and 54B. A planarization process (e.g., CMP) is performed to remove the excessive gate electrode layer 315, the high-k dielectric layer 313, the interfacial layer 311, and the hard mask layers 305 and 317 above the gate spacers 306. The gate spacers 106 may also act as an etch stop layer for etching the gate electrode layer 315, the high-k dielectric layer 313, the interfacial layer 311, and the hard mask layers 305 and 217. Therefore, a (metal) gate structure G3 including the gate electrode layer 315, the high-k dielectric layer 313, and the interfacial layer 311 can be formed in the recesses R34 to surround the channel layer 302 suspended in the recesses R34. In some embodiments, the gate structure G3 may be the final gate of a GAA FET. Therefore, the semiconductor structure can include the transistors PG_{R1}, PG_{L1}, PG_{R2}, PG_{L2}. The transistor PG_{L1} is over the transistor PD_{L}, and the transistor PG_{R2} is over the transistor PD_{R}. The transistors PG_{R1}, PG_{L1}, PG_{R2}, PG_{L2} each can include the channel layer 302, the gate structure G3 wrapping around the channel layer 302, and the source/drain regions 308 on opposite sides of the gate structure G3 and connected to the channel layer 302. In some embodiments, the transistors PG_{R1}, PG_{L1}, PG_{R2}, PG_{L2} can be interchangeably referred to as top-tier transistors.

Reference is made to FIGS. 55A and 55B. An interconnect structure 322 can be formed over the transistors PG_{R1}, PG_{L1}, PG_{R2}, PG_{L2}. In some embodiments, the interconnect structure 322 can be interchangeable referred to as a back end of line (BEOL) structure. The interconnect structure 322 may include an inter-metal dielectric 323 and the conductive interconnect including the bit lines BL and BLB, and the word line WL in the inter-metal dielectric 223. In some embodiments, the bit lines BL and BLB can be formed in a first metal layer M1 at a same elevation. In some embodiments, the word line WL can be formed in a second metal layer M2 at an elevation higher than the elevation of the bit lines BL and BLB. The conductive interconnect of the interconnect structure 322 may further include contacts 403a, 403b, 403c, 403d, 403c, 403f, 403g, and 403h. The contacts 403a and 403b can be formed on the non-sharing source/drain regions 308 of the transistors PG_{L1} and PG_{L2} and electrically connect to the overlying bit line BL. The contacts 403e and 403f can be formed on the non-sharing source/drain regions 308 of the transistor PG_{R1} and PG_{R2} and be electrically connected to the overlying bit line BLB. The contacts 403c, 403d, 403g, and 403h can be formed on the gate structures G3 of the transistors PG_{R1}, PG_{L1}, PG_{R2}, PG_{L2} and electrically connect to the overlying word line WL.

In some embodiments, the inter-metal dielectric 323 may include materials such as tetraethylorthosilicate (TEOS)-formed oxide, un-doped silicate glass, or doped silicon oxide such as borophosphosilicate glass (BPSG), fused silica glass (FSG), dielectric materials. In some embodiments, the bit lines BL and BLB, the word line WL, the read word line WL, and the contacts 403c, 403d, 403g, and 403h can be made of tungsten, platinum, aluminum, ruthenium, molybdenum, copper, nickel, cobalt, titanium, tantalum, titanium nitride, tantalum nitride, nickel silicide, cobalt silicide, Ag, Au, WN, RuO, TaC, TaSiN, TaCN, TiAl, TiAlN, or other suitable materials.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an improved static random access memory (SRAM) bit-cell configurations, focusing on read-enhanced and dual-port versions, both utilizing a three-tier architecture with 8 transistors (8T), maintaining the same physical footprint (e.g., 4 transistors footprint) as a standard 6T high-density SRAM bit-cell. The read-enhanced SRAM Bit-cell (see FIG. 3A) can incorporate two pairs of pass-gate transistors on the top-tier, doubling the transistor strength for improved read operations without increasing the bit-cell area. The dual-port SRAM bit-cell (see FIG. 3B) can incorporates two pairs of pass-gate transistors, each controlled by separate word lines, allowing independent accesses to the memory cell, which supports operations like simultaneous reads/writes. Additionally, the read-enhanced/dual-port SRAM Bit-cell can have the same transistor configuration as the 6T SRAM bit-cell for the pull-down and pull-up transistors.

In some embodiments, a method includes forming a first bottom-tier pull-up transistor (e.g., transistors PU_{L} illustrated in FIGS. 3A and 3B) and a second bottom-tier pull-up transistor (e.g., transistors PU_{R} illustrated in FIGS. 3A and 3B) over a substrate (e.g., substrate 100 illustrated in FIG. 55B), wherein the first and second bottom-tier pull-up transistors are comprised in a memory cell (e.g., SRAM cell 10a/10b illustrated in FIG. 3A/3B); forming a first middle-tier pull-down transistor (e.g., transistors PD_{L} illustrated in FIGS. 3A and 3B) and a second middle-tier pull-down transistor (e.g., transistors PD_{R} illustrated in FIGS. 3A and 3B) over the first and second bottom-tier pull-up transistors, wherein the first and second middle-tier pull-down transistors are comprised in the memory cell; forming a first top-tier pass-gate transistor (e.g., transistors PG_{L1} illustrated in FIGS. 3A and 3B), a second top-tier pass-gate transistor (e.g., transistors PG_{L2} illustrated in FIGS. 3A and 3B), a third top-tier pass-gate transistor (e.g., transistors PG_{R1} illustrated in FIGS. 3A and 3B), and a fourth top-tier pass-gate transistor (e.g., transistors PG_{R2} illustrated in FIGS. 3A and 3B) over the first and second middle-tier pull-down transistors, wherein the first, second, third, and fourth top-tier pass-gate transistors are comprised in the memory cell. In some embodiments, the memory cell has a footprint on the substrate, and the footprint encompasses up to four transistors located on a same level. In some embodiments, a footprint of the first middle-tier pull-down transistor overlaps with a footprint of the first bottom-tier pull-up transistor on the substrate, and a footprint of the second middle-tier pull-down transistor overlaps with a footprint of the second bottom-tier pull-up transistor on the substrate. In some embodiments, a footprint of the first top-tier pass-gate transistor overlaps with a footprint of the first middle-tier pull-down transistor on the substrate, and a footprint of the fourth top-tier pass-gate transistor overlaps with a footprint of the second middle-tier pull-down transistor on the substrate. In some embodiments, the method further includes forming a word line over the first, second, third, and fourth top-tier pass-gate transistors, wherein gates of the first, second, third, and fourth top-tier pass-gate transistors are electrically coupled to the word line. In some embodiments, the method further includes forming a bit line and a bit line bar over the word line, wherein source/drain nodes of the first and second top-tier pass-gate transistors are electrically coupled to the bit line, and source/drain nodes of the third and fourth top-tier pass-gate transistors are electrically coupled to the bit line bar. In some embodiments, the method further includes forming a first word line and a second word line over the first, second, third, and fourth top-tier pass-gate transistors, wherein gates of the first and second top-tier pass-gate transistors are electrically coupled to the first word line, and gates of the third and fourth top-tier pass-gate transistors are electrically coupled to the second word line. In some embodiments, the method further includes forming a first bit line, a second bit line, a first bit line bar, and a second bit line bar over the first and second word line, wherein a source/drain node of the first top-tier pass-gate transistor is electrically coupled to the first bit line, a source/drain node of the second top-tier pass-gate transistor is electrically coupled to the first bit line bar, a source/drain node of the third top-tier pass-gate transistor is electrically coupled to the second bit line, and a source/drain node of the fourth top-tier pass-gate transistor is electrically coupled to the second bit line bar. In some embodiments, the method further includes forming a back-side voltage source line over the substrate prior to forming the first and second bottom-tier pull-up transistors, wherein a source/drain node of the first bottom-tier pull-up transistor and a source/drain node of the second bottom-tier pull-up transistor are electrically coupled to the back-side voltage source line. In some embodiments, the method further includes forming a first back-side ground line and a second back-side ground line over the substrate prior to prior to forming the first and second bottom-tier pull-up transistors, wherein a source/drain node of the first middle-tier pull-down transistor is electrically coupled to the first back-side ground line, and a source/drain node of the second middle-tier pull-down transistor is electrically coupled to the second back-side ground line.

In some embodiments, a method includes forming a first semiconductive nanostructure (e.g., channel layer 102/202 illustrated in FIGS. 6 and 7) over a substrate (e.g., substrate 100 illustrated in FIG. 55B) at a first level height, wherein the first semiconductive nanostructure is comprised in a static random access memory (SRAM) cell (e.g., SRAM cell 10a/10b illustrated in FIG. 3A/3B); forming first epitaxial structures (e.g., source/drain region 108/208 illustrated in FIGS. 3A and 3B) on opposite sides of the first semiconductive nanostructure; forming a first gate structure (e.g., gate structure G1/G2 illustrated in FIG. 3A/3B) wrapping around the first semiconductive nanostructure; forming second, third, fourth, and fifth semiconductive nanostructures (e.g., channel layer 302 illustrated in FIGS. 8A and 8B) over the substrate at a second level height, wherein the second, third, fourth, and fifth semiconductive nanostructures are comprised in the SRAM cell; forming second epitaxial structures (e.g., source/drain region 308 illustrated in FIGS. 3A and 3B) on opposite sides of the second semiconductive nanostructure, third epitaxial structures (e.g., source/drain region 308 illustrated in FIGS. 3A and 3B) on opposite sides of the third semiconductive nanostructure, fourth epitaxial structures (e.g., source/drain region 308 illustrated in FIGS. 3A and 3B) on opposite sides of the fourth semiconductive nanostructure, and fifth epitaxial structures (e.g., source/drain region 308 illustrated in FIGS. 3A and 3B) on opposite sides of the fifth semiconductive nanostructure; forming a second gate structure (e.g., gate structure G3 illustrated in FIG. 3A/3B) wrapping around the second semiconductive nanostructure, a third gate structure (e.g., gate structure G3 illustrated in FIG. 3A/3B) wrapping around the third semiconductive nanostructure, a fourth gate structure (e.g., gate structure G3 illustrated in FIG. 3A/3B) wrapping around the fourth semiconductive nanostructure, and a fifth gate structure (e.g., gate structure G3 illustrated in FIG. 3A/3B) wrapping around the fifth semiconductive nanostructure. In some embodiments, the second level height is higher than the first level height. In some embodiments, the first semiconductive nanostructure, the first epitaxial structures, and the first gate structure collectively form a pull-up transistor or a pull-down transistor of the SRAM cell. In some embodiments, the second semiconductive nanostructure, the second epitaxial structures, and the second gate structure form a first pass-gate transistor, the third semiconductive nanostructure, the third epitaxial structures, and the third gate structure form a second pass-gate transistor, the fourth semiconductive nanostructure, the fourth epitaxial structures, and the fourth gate structure form a third pass-gate transistor, and the fifth semiconductive nanostructure, the fifth epitaxial structures, and the fifth gate structure form a fourth pass-gate transistor. In some embodiments, the method further includes forming a sixth semiconductive nanostructure over the substrate at a third level height, wherein the sixth semiconductive nanostructure is comprised in the SRAM cell; forming sixth epitaxial structures on opposite sides of the sixth semiconductive nanostructure; forming a sixth gate structure wrapping around the sixth semiconductive nanostructure.

In some embodiments, the semiconductor structure includes a plurality of back-side power lines (e.g., voltage source line VDD and ground lines VSS-1, VSS-2 illustrated in FIGS. 3A and 3B) and a memory cell (e.g., SRAM cell 10a/10b illustrated in FIG. 3A/3B). The back-side power lines are over a semiconductive substrate (e.g., substrate 100 illustrated in FIG. 55B). The memory cell is over the back-side power lines. The memory cell includes first and second pull-up transistors (e.g., transistors PU_{L} and PU_{R} illustrated in FIGS. 3A and 3B) at a first level height, first and second pull-down transistors (e.g., transistors PD_{L} and PD_{R} illustrated in FIGS. 3A and 3B) at a second level height different than the first level height, and first, second, third, and fourth pass-gate transistors (e.g., transistors PG_{L1}, PG_{L2}, PG_{R1}, and PG_{R2}, illustrated in FIGS. 3A and 3B) at a third level height different than the first and second level heights. In some embodiments, the semiconductor structure further includes a word line over the semiconductive substrate at a fourth level height, wherein gates of the first, second, third, and fourth pass-gate transistors are electrically coupled to the word line. In some embodiments, the semiconductor structure further includes a bit line and a bit line bar. The bit line is over the semiconductive substrate at a fifth level height. The bit line bar is over the semiconductive substrate at the fifth level height. Source/drain nodes of the first and second pass-gate transistors are electrically coupled to the bit line, and source/drain nodes of the third and fourth pass-gate transistors are electrically coupled to the bit line bar. In some embodiments, the semiconductor structure further includes a first word line and a second word line. The first word line is over the semiconductive substrate at a fourth level height. The second word line is over the semiconductive substrate at the fourth level height. Gates of the first and second pass-gate transistors are electrically coupled to the first word line, and gates of the third and fourth pass-gate transistors are electrically coupled to the second word line. In some embodiments, the semiconductor structure further includes a first bit line and a second bit line. The first bit line is over the semiconductive substrate at a fifth level height. The second bit line is over the semiconductive substrate at the fifth level height. A source/drain node of the first pass-gate transistor is electrically coupled to the first bit line, and a source/drain node of the third pass-gate transistor is electrically coupled to the second bit line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first bottom-tier pull-up transistor and a second bottom-tier pull-up-transistor over a substrate, wherein the first and second bottom-tier pull-up transistors are comprised in a memory cell;
forming a first middle-tier pull-down transistor and a second middle-tier pull-down transistor over the first and second bottom-tier pull-up transistors, wherein the first and second middle-tier pull-down transistors are comprised in the memory cell; and
forming a first top-tier pass-gate transistor, a second top-tier pass-gate transistor, a third top-tier pass-gate transistor, and a fourth top-tier pass-gate transistor over the first and second middle-tier pull-down transistors, wherein the first, second, third, and fourth top-tier pass-gate transistors are comprised in the memory cell.

2. The method of claim 1, wherein the memory cell has a footprint on the substrate, and the footprint encompasses up to four transistors located on a same level.

3. The method of claim 1, wherein a footprint of the first middle-tier pull-down transistor overlaps with a footprint of the first bottom-tier pull-up transistor on the substrate, and a footprint of the second middle-tier pull-down transistor overlaps with a footprint of the second bottom-tier pull-up transistor on the substrate.

4. The method of claim 1, wherein a footprint of the first top-tier pass-gate transistor overlaps with a footprint of the first middle-tier pull-down transistor on the substrate, and a footprint of the fourth top-tier pass-gate transistor overlaps with a footprint of the second middle-tier pull-down transistor on the substrate.

5. The method of claim 1, further comprising:
forming a word line over the first, second, third, and fourth top-tier pass-gate transistors, wherein gates of the first, second, third, and fourth top-tier pass-gate transistors are electrically coupled to the word line.

6. The method of claim 5, further comprising:
forming a bit line and a bit line bar over the word line, wherein source/drain nodes of the first and second top-tier pass-gate transistors are electrically coupled to the bit line, and source/drain nodes of the third and fourth top-tier pass-gate transistors are electrically coupled to the bit line bar.

7. The method of claim 1, further comprising:
forming a first word line and a second word line over the first, second, third, and fourth top-tier pass-gate transistors, wherein gates of the first and second top-tier pass-gate transistors are electrically coupled to the first word line, and gates of the third and fourth top-tier pass-gate transistors are electrically coupled to the second word line.

8. The method of claim 7, further comprising:
forming a first bit line, a second bit line, a first bit line bar, and a second bit line bar over the first and second word line, wherein a source/drain node of the first top-tier pass-gate transistor is electrically coupled to the first bit line, a source/drain node of the second top-tier pass-gate transistor is electrically coupled to the first bit line bar, a source/drain node of the third top-tier pass-gate transistor is electrically coupled to the second bit line, and a source/drain node of the fourth top-tier pass-gate transistor is electrically coupled to the second bit line bar.

9. The method of claim 1, further comprising:
forming a back-side voltage source line over the substrate prior to forming the first and second bottom-tier pull-up transistors, wherein a source/drain node of the first bottom-tier pull-up transistor and a source/drain node of the second bottom-tier pull-up transistor are electrically coupled to the back-side voltage source line.

10. The method of claim 1, further comprising
forming a first back-side ground line and a second back-side ground line over the substrate prior to prior to forming the first and second bottom-tier pull-up transistors, wherein a source/drain node of the first middle-tier pull-down transistor is electrically coupled to the first back-side ground line, and a source/drain node of the second middle-tier pull-down transistor is electrically coupled to the second back-side ground line.

11. A method, comprising:
forming a first semiconductive nanostructure over a substrate at a first level height, wherein the first semiconductive nanostructure is comprised in a static random access memory (SRAM) cell;
forming first epitaxial structures on opposite sides of the first semiconductive nanostructure;
forming a first gate structure wrapping around the first semiconductive nanostructure;
forming second, third, fourth, and fifth semiconductive nanostructures over the substrate at a second level height, wherein the second, third, fourth, and fifth semiconductive nanostructures are comprised in the SRAM cell;
forming second epitaxial structures on opposite sides of the second semiconductive nanostructure, third epitaxial structures on opposite sides of the third semiconductive nanostructure, fourth epitaxial structures on opposite sides of the fourth semiconductive nanostructure, and fifth epitaxial structures on opposite sides of the fifth semiconductive nanostructure; and
forming a second gate structure wrapping around the second semiconductive nanostructure, a third gate structure wrapping around the third semiconductive nanostructure, a fourth gate structure wrapping around the fourth semiconductive nanostructure, and a fifth gate structure wrapping around the fifth semiconductive nanostructure.

12. The method of claim 11, wherein the second level height is higher than the first level height.

13. The method of claim 11, wherein the first semiconductive nanostructure, the first epitaxial structures, and the first gate structure collectively form a pull-up transistor or a pull-down transistor of the SRAM cell.

14. The method of claim 11, wherein the second semiconductive nanostructure, the second epitaxial structures, and the second gate structure form a first pass-gate transistor, the third semiconductive nanostructure, the third epitaxial structures, and the third gate structure form a second pass-gate transistor, the fourth semiconductive nanostructure, the fourth epitaxial structures, and the fourth gate structure form a third pass-gate transistor, and the fifth semiconductive nanostructure, the fifth epitaxial structures, and the fifth gate structure form a fourth pass-gate transistor.

15. The method of claim 11, further comprising:
forming a sixth semiconductive nanostructure over the substrate at a third level height, wherein the sixth semiconductive nanostructure is comprised in the SRAM cell;
forming sixth epitaxial structures on opposite sides of the sixth semiconductive nanostructure; and
forming a sixth gate structure wrapping around the sixth semiconductive nanostructure.

16. A semiconductor structure, comprising:
a plurality of back-side power lines over a semiconductive substrate; and
a memory cell over the back-side power lines, the memory cell comprising first and second pull-up transistors at a first level height, first and second pull-down transistors at a second level height different than the first level height, and first, second, third, and fourth pass-gate transistors at a third level height different than the first and second level heights.

17. The semiconductor structure of claim 16, further comprising:
a word line over the semiconductive substrate at a fourth level height, wherein gates of the first, second, third, and fourth pass-gate transistors are electrically coupled to the word line.

18. The semiconductor structure of claim 17, further comprising:
a bit line over the semiconductive substrate at a fifth level height; and
a bit line bar over the semiconductive substrate at the fifth level height, wherein source/drain nodes of the first and second pass-gate transistors are electrically coupled to the bit line, and source/drain nodes of the third and fourth pass-gate transistors are electrically coupled to the bit line bar.

19. The semiconductor structure of claim 16, further comprising:
a first word line over the semiconductive substrate at a fourth level height; and
a second word line over the semiconductive substrate at the fourth level height, wherein gates of the first and second pass-gate transistors are electrically coupled to the first word line, and gates of the third and fourth pass-gate transistors are electrically coupled to the second word line.

20. The semiconductor structure of claim 19, further comprising:
a first bit line over the semiconductive substrate at a fifth level height; and
a second bit line over the semiconductive substrate at the fifth level height, wherein a source/drain node of the first pass-gate transistor is electrically coupled to the first bit line, and a source/drain node of the third pass-gate transistor is electrically coupled to the second bit line.
